(19) United States
(12) Patent Application Publication
(10) Pub. No.: US 2024/0276780 A1
(43) Pub. Date: Aug. 15, 2024

(54) DISPLAY PANEL AND MANUFACTURING METHOD OF THE SAME

(71) Applicant: Samsung Display Co., LTD., Yongin-si (KR)

(72) Inventors: HYUNEOK SHIN, Yongin-si (KR); JOONYONG PARK, Yongin-si (KR); SUKYOUNG YANG, Yongin-si (KR)

(21) Appl. No.: 18/389,557

(22) Filed: Nov. 14, 2023

(30) Foreign Application Priority Data
Feb. 15, 2023 (KR) 10-2023-0020043

(51) Int. Cl. H10K 59/122; H10K 59/12

(52) U.S. Cl. CPC H10K 59/122; H10K 59/1201

(57) ABSTRACT

A display panel includes: a base layer; an anode disposed on the base layer; a pixel-definition layer defining a light emitting opening which exposes a portion of the anode and disposed on the base layer; a first partition wall defining a first partition-wall opening therein overlapping the light emitting opening in a plan view and disposed on the pixel-definition layer; a second partition wall defining a second partition-wall opening therein overlapping the first partition-wall opening in the plan view and disposed on the first partition wall; a cathode in contact with the first partition wall, and a light emitting pattern. The first partition wall includes a conductive material. The second partition wall includes a first upper layer including an inorganic material, and a second upper layer including a conductive material and disposed on the first upper layer.

This application claims priority to Korean Patent Application No. 10-2023-0020043, filed on Feb. 15, 2023, and all the benefits accruing therefrom under 35 U.S.C. § 119, the content of which in its entirety is herein incorporated by reference.

### BACKGROUND

The present disclosure herein relates to a display panel and a manufacturing method of the same, and more particularly, to a display panel with improved process reliability and a manufacturing method of the same.

A display device is activated in response to an electrical signal. The display device may include a display panel which displays images. In the display panel, an organic light emitting display panel has a low power consumption, a high luminance, and a high response speed.

Among display panels, an organic light emitting display panel includes an anode, a cathode, and a light emitting pattern. The light emitting pattern is divided for each light emitting region, and the cathode provides a common voltage to each light emitting region.

### SUMMARY

The present disclosure provides a light emitting element formed without using a metal mask, and a display panel including the light emitting element.

The present disclosure also provides a light emitting element with improved process reliability, and a display panel including the light emitting element.

The present disclosure also provides a manufacturing method of a display panel including a light emitting element with improved process reliability, the method not using a metal mask.

An embodiment of the invention provides a display panel including: a base layer: an anode disposed on the base layer; a pixel-definition layer having a light emitting opening which exposes a portion of the anode, and disposed on the base layer; a first partition wall defining a first partition-wall opening therein overlapping the light emitting opening in a plan view, and disposed on the pixel-definition layer: a second partition wall defining a second partition-wall opening therein overlapping the first partition-wall opening in the plan view, and disposed on the first partition wall: a cathode having at least a portion thereof disposed in the first partition-wall opening, being in contact with the first partition wall, and disposed on the anode; and a light emitting pattern disposed between the anode and the cathode, where the first partition wall includes a conductive material, and the second partition wall includes a first upper layer including an inorganic material, and a second upper layer including a conductive material and disposed on the first upper layer.

In an embodiment, the first upper layer may include at least one of silicon nitride, silicon oxide, silicon oxynitride, or aluminum oxide.

In an embodiment, the second upper layer may include at least one of a metal or a metal nitride.

In an embodiment, the second upper layer may include at least one of tungsten, molybdenum, titanium nitride, or aluminum nitride.

In an embodiment, the display panel may further include a first dummy pattern disposed on the second partition wall, and the first dummy pattern may include: a 1-1 dummy layer spaced apart from the light emitting pattern, and including the same material as a material of the light emitting pattern, and a 1-2 dummy layer spaced apart from the cathode, and including the same material as a material of the cathode.

In an embodiment, the first upper layer may include a first upper inner surface defining a first upper region of the second partition-wall opening, and the second upper layer comprises a second upper inner surface defining a second upper region of the second partition-wall opening, and the first upper inner surface may be recessed in a direction farther away from the light emitting opening than the second upper inner surface.

In an embodiment, the display panel may further include an encapsulation inorganic pattern which covers the cathode, and the encapsulation inorganic pattern may be in contact with the first upper inner surface.

In an embodiment, the encapsulation inorganic pattern may cover the entire first upper inner surface.

In an embodiment, the first upper layer may include the same material as a material of the encapsulation inorganic pattern.

In an embodiment, the first partition wall may include a first lower layer including a first lower inner surface defining a first lower region of the first partition-wall opening, and a second lower layer including a second lower inner surface defining a second lower region of the first partition-wall opening, and the first lower inner surface may be recessed in a direction farther away from the light emitting opening than the second lower inner surface.

In an embodiment, the first upper inner surface may be recessed in a direction farther away from the light emitting opening than the second lower inner surface.

In an embodiment, a width in which the first upper inner surface is recessed from the second lower inner surface may be greater than or equal to a width in which the first lower inner surface is recessed from the second lower inner surface.

In an embodiment, the display panel may further include encapsulation inorganic patterns, some of which are disposed on the cathode and cover the cathode, and others of which are disposed on the second partition wall, and the encapsulation inorganic patterns may cover a lower surface of the second upper layer exposed from the first upper layer, and may cover at least a portion of an upper surface of the second lower layer exposed from the first upper layer.

In an embodiment, the display panel may further include a second dummy pattern disposed on a portion of the second lower layer exposed from the first upper layer, and the second dummy pattern may include a 2-1 dummy layer spaced apart from the light emitting pattern, and including the same material as a material of the light emitting pattern, and a 2-2 dummy layer spaced apart from the cathode, and including the same material as a material of the cathode, and the encapsulation inorganic pattern may cover the second dummy pattern.

In an embodiment, the cathode may be in contact with at least a portion of the first lower inner surface.

In an embodiment, the display panel may further include encapsulation inorganic patterns, some of which are disposed on the cathode and cover the cathode, and others of which are disposed on the second partition wall, and the encapsulating inorganic patterns may be in contact with the second lower inner surface, the first upper inner surface, the second upper inner surface, and a portion of the first lower inner surface not in contact with the cathode.

In an embodiment, the first lower layer may include a metal, and the second lower layer may include at least one of a metal or a metal nitride.

In an embodiment, a first tip portion may be defined in the first partition wall by the second lower layer protruding more than the first lower layer, and a second tip portion may be defined in the second partition wall by the second upper layer protruding more than the first upper layer.

In an embodiment, a bias voltage may be configured to be applied to the first partition wall.

In an embodiment of the invention, a method for manufacturing a display panel includes providing a preliminary display panel including a base layer, an anode disposed on the base layer, and a preliminary pixel-definition layer disposed on the base layer and covering the anode, forming, on the preliminary pixel-definition layer, a first preliminary partition wall including a first lower layer and a second lower layer, forming, on the first preliminary partition wall, a second preliminary partition wall including a first upper layer having an inorganic material and a second upper layer disposed on the first upper layer, patterning the first upper layer and the second upper layer to form a second partition wall defining an upper partition-wall opening therein, patterning the first lower layer and the second lower layer to form a first partition wall defining a lower partition-wall opening therein, forming a light emitting pattern on the anode, and forming, on the light emitting pattern, a cathode in contact with the first partition wall.

In an embodiment, the patterning of the first upper layer and the second upper layer may include performing first etching on the first upper layer and the second upper layer to form a preliminary upper partition-wall opening on the second preliminary partition wall, and performing second etching on the first upper layer and the second upper layer to form the upper partition-wall opening from the preliminary upper partition-wall opening, and in the performing of the second etching, an etch rate of the first upper layer may be greater than an etch rate of the second upper layer.

In an embodiment, the performing of the first etching may be performed in a dry etch manner, and the performing of the second etching may be performed in a dry etch manner using hydrogen fluoride or in a wet etch manner using bromine water.

In an embodiment, the patterning of the first upper layer and the second upper layer may include performing first etching on the first upper layer and the second upper layer to form a preliminary upper partition-wall opening on the second preliminary partition wall, and performing second etching on the first upper layer to form the upper partition-wall opening from the preliminary upper partition-wall opening, and in the performing of the second etching, the second upper layer may not be etched.

In an embodiment, the second upper layer may include at least one of a metal or a metal nitride.

In an embodiment, the patterning of the first lower layer and the second lower layer may include performing third etching on the first lower layer and the second lower layer to form a preliminary lower partition-wall opening on the first preliminary partition wall, and performing fourth etching on the first lower layer and the second lower layer to form the lower partition-wall opening from the preliminary lower partition-wall opening, and in the performing of the fourth etching, an etch rate of the first lower layer may be greater than an etch rate of the second lower layer.

In an embodiment, the performing of the third etching may be performed in a dry etch manner, and the performing of the fourth etching may be performed in a wet etch manner.

In an embodiment, the first lower layer may include a metal, and the second lower layer may include at least one of a metal or a metal nitride.

In an embodiment, the method for manufacturing a display panel may further include, after the forming of the cathode, forming an encapsulation inorganic pattern which covers the cathode, and the first upper layer may include a first upper inner surface defining a first upper region of the upper partition-wall opening, and the second upper layer may include a second upper inner surface defining a second upper region of the upper partition-wall opening. The first upper inner surface may be recessed in a direction farther away from a light emitting region than the second upper inner surface, and the encapsulating inorganic pattern may cover the first upper inner surface, the second upper inner surface, and a lower surface of the second upper layer exposed from the first upper layer and connected to the second upper inner surface.

In an embodiment, the method for manufacturing a display panel may further include, after the patterning of the first lower layer and the second lower layer and before the forming of the light emitting pattern on the anode, patterning the preliminary pixel-definition layer to form a pixel-definition layer defining a light emitting opening therein, and at least a portion of the light emitting pattern is formed in the light emitting opening and the partition-wall opening.

### BRIEF DESCRIPTION OF THE FIGURES

The accompanying drawings are included to provide a further understanding of the invention, and are incorporated in and constitute a part of this specification. The drawings illustrate exemplary embodiments of the invention and, together with the description, serve to explain principles of the invention. In the drawings:

FIG. 1A is a perspective view of a display device according to an embodiment of the present invention;

FIG. 1B is an exploded perspective view of a display device according to an embodiment of the invention;

FIG. 2 is a cross-sectional view of a display panel according to an embodiment of the invention;

FIG. 3 is a plan view of a display panel according to an embodiment of the invention;

FIG. 4 is a plan view of an enlarged portion of a display region of a display panel according to an embodiment of the invention;

FIG. 5 is a cross-sectional view of an enlarged region of a display panel according to an embodiment of the invention;

FIG. 6 is a cross-sectional view of a display panel according to an embodiment of the invention taken along line I-I′ of FIG. 4; and

FIG. 7A to FIG. 7N are cross-sectional views showing some of steps of a method for manufacturing a display panel according to an embodiment of the invention.

### DETAILED DESCRIPTION

In the present disclosure, when an element (or a region, a layer, a portion, etc.) is referred to as being “on,” “connected to,” or “coupled to” another element, it means that the element may be directly disposed on/connected to/coupled to the other element, or that a third element may be disposed therebetween.

Like reference numerals refer to like elements. Also, in the drawings, the thickness, the ratio, and the dimensions of elements are exaggerated for an effective description of technical contents. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” The term “and/or” includes any and all combinations of one or more of which associated elements may define.

It will be understood that, although the terms “first,” “second,” etc. may be used herein to describe various elements, these elements should not be limited by these terms. These terms are only used to distinguish one element from another. For example, a first element may be referred to as a second element, and a second element may also be referred to as a first element in a similar manner without departing the scope of rights of the present invention. The terms of a singular form may include the terms of a plural form unless the context clearly indicates otherwise.

In addition, terms such as “below,” “lower,” “above,” “upper,” and the like are used to describe the relationship of the components shown in the drawings. The terms are used as a relative concept and are described with reference to the direction indicated in the drawings.

It should be understood that the term “comprise,” or “have” is intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the present invention pertains. It is also to be understood that terms such as terms defined in commonly used dictionaries should be interpreted as having meanings consistent with the meanings in the context of the related art, and should not be interpreted in too ideal a sense or an overly formal sense unless explicitly defined herein.

Hereinafter, embodiments of the invention will be described with reference to the accompanying drawings.

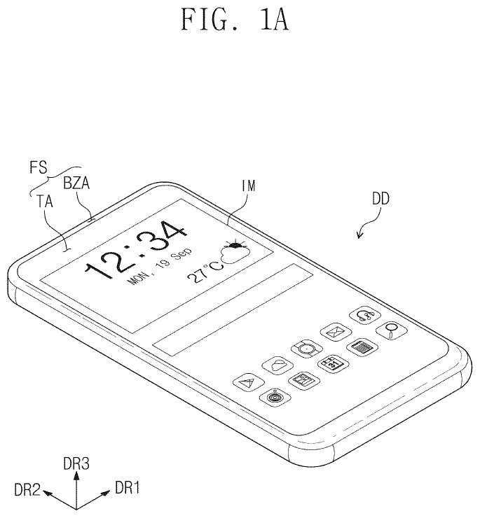

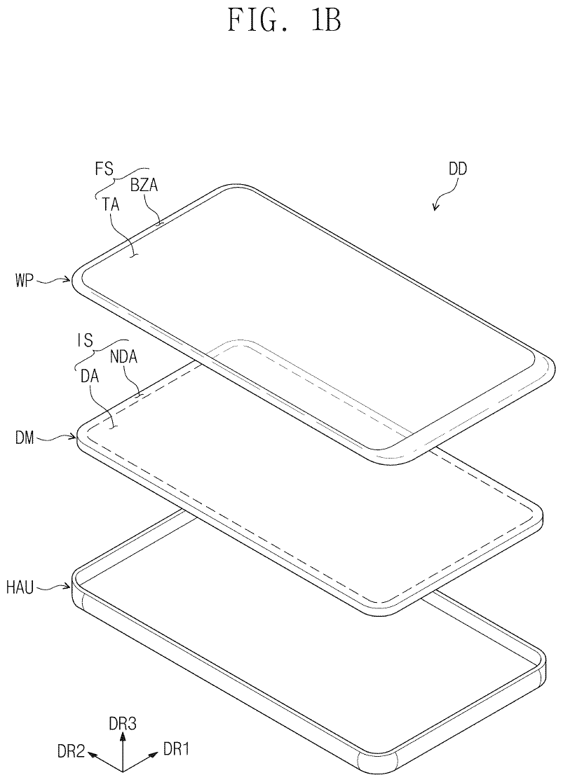

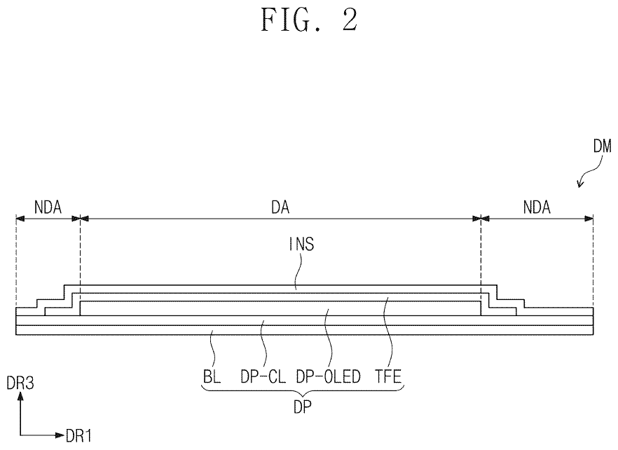

FIG. 1A is a perspective view of a display device according to an embodiment of the present invention. FIG. 1B is an exploded perspective view of a display device according to an embodiment of the invention. FIG. 2 is a cross-sectional view of a display panel according to an embodiment of the invention.

In an embodiment, a display device DD may be a large electronic device such as a television, a monitor, or an external advertisement board. Also, the display device DD may be a small-and-medium-sized electronic device such as a personal computer, a laptop computer, a personal digital terminal, a car navigation system unit, a game console, a smart phone, a tablet, or a camera. However, these are merely exemplary embodiments, and a different display device may be employed as long as it does not depart from the invention. In the present embodiment, the display device DD is exemplarily illustrated as a smart phone.

Referring to FIG. 1A, FIG. 1B, and FIG. 2, the display device DD may display an image IM toward a third direction DR3 on a display surface FS parallel to each of a first direction DR1 and a second direction DR2. The image IM may include both a moving image and a still image. In FIG. 1, as an example of the image IM, a watch window and icons are illustrated. The display surface FS on which the image IM is displayed may correspond to a front surface of the display device DD.

In the present embodiment, a front surface (or an upper surface) and a rear surface (or a lower surface) of each member are defined on the basis of a direction in which the image IM is displayed. The front surface and the rear surface oppose each other in the third direction DR3 and a normal direction of each of the front surface and the rear surface may be parallel to the third direction DR3. Meanwhile, directions indicated by the first to third directions DR1, DR2, and DR3 are a relative concept, and may be converted to different directions. In the present disclosure, “on a plane” may mean when viewed in the third direction DR3 (e.g., in a plan view).

As illustrated in FIG. 1B, the display device DD according to the present embodiment may include a window WP, a display module DM, and a housing HAU. The window WP and the housing HAU may be coupled to each other to configure the appearance of the display device DD.

The window WP may include an optically transparent insulation material. In an embodiment, for example, the window WP may include glass or plastic. The front surface of the window WP may define the display surface FS of the display device DD. The display surface FS may include a transmission region TA and a bezel region BZA. The transmission region TA may be an optically transparent region. In an embodiment, for example, the transmission unit TA may be a region having a visible light transmittance of about 90% or higher.

The bezel region BZA may be a region having a relatively low light transmittance compared to the transmission region TA. The bezel region BZA may define the shape of the transmission region TA. The bezel region BZA is adjacent to the transmission region TA, and may surround the transmission region TA. Meanwhile, this is only exemplarily illustrated, and in the window WP according to an embodiment of the invention, the bezel region BZA may be omitted. The window WP may include at least one functional layer among a fingerprint prevention layer, a hard coating layer, and a reflection prevention layer, and is not limited to any one embodiment.

The display module DM may be disposed in a lower portion of the window WP. The display module DM may be a component which substantially generates the image IM. The image IM generated in the display module DM is displayed on the display surface IS of the display module DM, and is visually recognized by a user from the outside through the transmission region TA.

The display module DM includes a display region DA and a non-display region NDA. The display region DA may be a region activated according to an electrical signal. The non-display region NDA is adjacent to the display region DA. The non-display region NDA may surround the display region DA. The non-display region NDA is a region covered by the bezel region BZA, and may not be visually recognized from the outside.

As illustrated in FIG. 2, the display module DM according to the present embodiment may include a display panel DP and an input sensor INS. Although not separately illustrated, the display device DD according to an embodiment of the invention may further include a protective member disposed on a lower surface of the display panel DP or a reflection prevention member and/or a window member disposed on an upper surface of the input sensor INS.

The display panel DP may be a light emitting type display panel, and is not particularly limited. In an embodiment, for example, the display panel DP may be an organic light emitting display panel or an inorganic light emitting display panel. A light emitting layer in the organic light emitting display panel includes an organic light emitting material. A light emitting layer in the inorganic light emitting display panel includes a quantum dot, a quantum rod, or a micro LED. Hereinafter, the display panel DP is described as an organic light emitting display panel.

The display panel DP may include a base layer BL, a circuit element layer DP-CL disposed on the base layer BL, a display element layer DP-OLED, and an encapsulation layer TFE. The input sensor INS may be directly disposed on the encapsulation layer TFE. In the present specification, “Component A is directly disposed on Component B” means that no adhesive layer is disposed between Component A and Component B.

The base layer BL may include at least one plastic film. The base layer BL is a flexible substrate, and may include a plastic substrate, a glass substrate, a metal substrate, an organic/inorganic composite material substrate, or the like. In the present specification, the display region DA and the non-display region NDA may be viewed as being defined in the base layer BL, and in this case, components disposed on the base layer BL may be viewed as being disposed overlapping the display region DA or the non-display region NDA in a plan view.

The circuit element layer DP-CL includes at least one insulation layer and a circuit element. The insulation layer includes at least one inorganic layer and at least one organic layer. The circuit element includes signal lines, a driving circuit of a pixel, and the like.

The display element layer DP-OLED includes a conductive partition wall and a light emitting element. The light emitting element includes an anode, a light emitting pattern, and a cathode, and the light emitting pattern may include at least a light emitting layer.

The encapsulation layer TFE includes a plurality of thin films. Some of the thin films are disposed to improve optical efficiency, and some of the thin films are disposed to protect organic light emitting diodes.

The input sensor INS obtains the coordinate information of an external input. The input sensor INS may have a multi-layered structure. The input sensor INS may include a single-layered or multi-layered conductive layer. The input sensor INS may include a single-layered or multi-layered insulation layer. The input sensor INS may sense an external input, for example, in a capacitive manner. In the invention, the operation method of the input sensor INS is not particularly limited, and in an embodiment of the invention, the input sensor INS may sense an external input in an electromagnetic induction manner or pressure sensing manner. In another embodiment of the invention, the input sensor INS may be omitted.

As illustrated in FIG. 1B, the housing HAU may be coupled to the window WP. The housing HAU may be coupled to the window WP and provide a predetermined internal space. The display module DM may be accommodated in the internal space.

The housing HAU may include a material having a relatively high rigidity. In an embodiment, for example, the housing HAU may include glass, plastic, or a metal, or may include a plurality of frames and/or plates composed of a combination thereof. The housing HAU may stably protect components of the display device DD accommodated in the internal space from an external impact.

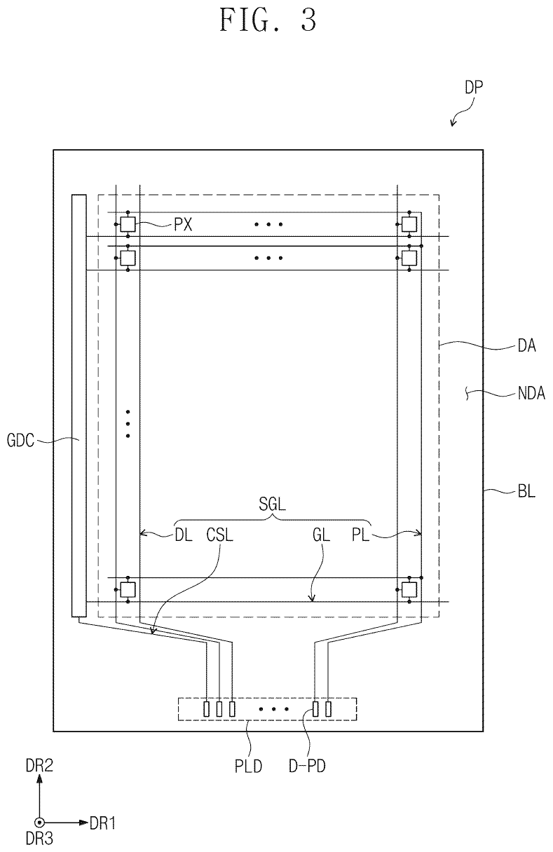

FIG. 3 is a plan view of a display panel according to an embodiment of the invention.

Referring to FIG. 3, the display panel DP ma include the base layer BL divided into the display region DA and the non-display region NDA described with reference to FIG. 2.

The display panel DP may include pixels PX disposed in the display region DA and signal lines SGL electrically connected to the pixels PX. The display panel DP may include a driving circuit GDC and a pad unit PLD disposed in the non-display region NDA.

The pixels PX may be arranged in the first direction DR1 and the second direction DR2. The pixels PX may include a plurality of pixel rows extended in the first direction DR1 and arranged in the second direction DR2, and a plurality of pixel columns extended in the second direction DR2 and arranged in the first direction DR1.

The signal lines SGL may include gate lines GL, data lines DL, a power line PL, and a control signal line CSL. Each of the gate lines GL may be connected to a corresponding pixel among the pixels PX, and each of the data lines DL may be connected to a corresponding pixel among the pixels PX. The power line PL may be electrically connected to the pixels PX. The control signal line CSL may be connected to the driving circuit GDC and provide control signals to the driving circuit GDC.

The driving circuit GDC may include a gate driving circuit. The gate driving circuit generates gate signals, and may sequentially output the generated gate signal to the gate lines GL. The gate driving circuit may further output another control signal to a pixel driving circuit.

The pad unit PLD may be a portion to which a flexible circuit board is connected. The pad unit PLD may include pixel pads D-PD, and the pixel pads D-PD may be pads for connecting the flexible circuit board to the display panel DP. Each of the pixel pads D-PD may be connected to a corresponding signal line among the signal lines SGL. The pixel pads D-PD may be connected to corresponding pixels PX through the signal lines SGL. In addition, any one pixel pad among the pixel pads D-PD may be connected to the driving circuit GDC.

In addition, the pad unit PLD may further include input pads. The input pads may be pads for connecting the flexible circuit board to the input sensor INS (see FIG. 2). However, the embodiment of the invention is not limited thereto, and the input pads may be disposed in the input sensor INS (see FIG. 2), and be connected to the pixel pads D-PD and a separate circuit board in another embodiment. Alternatively, the input sensor INS (see FIG. 2) may be omitted, and may not further include input pads.

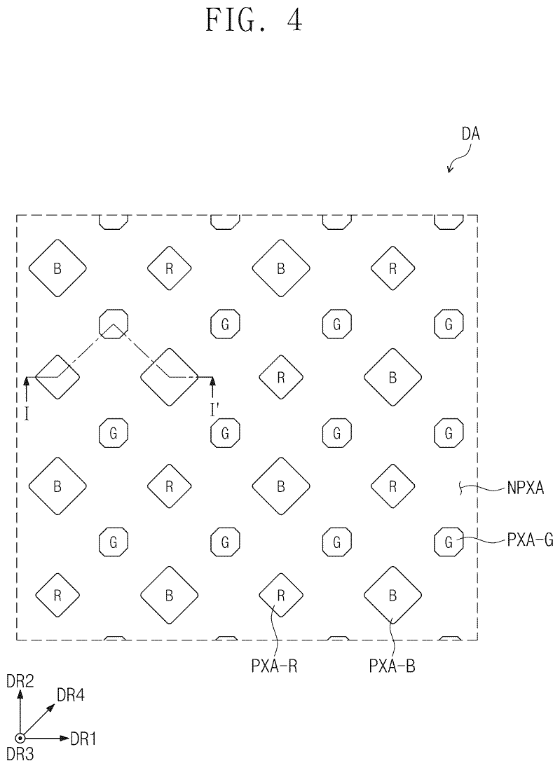

FIG. 4 is a plan view of an enlarged portion of a display region of a display panel according to an embodiment of the invention. FIG. 4 illustrates a plane of the display module DM (see FIG. 2) viewed on the display surface IS (see FIG. 2) of the display module DM (see FIG. 2), and shows an arrangement of light emitting regions PXA-R, PXA-G, and PXA-B.

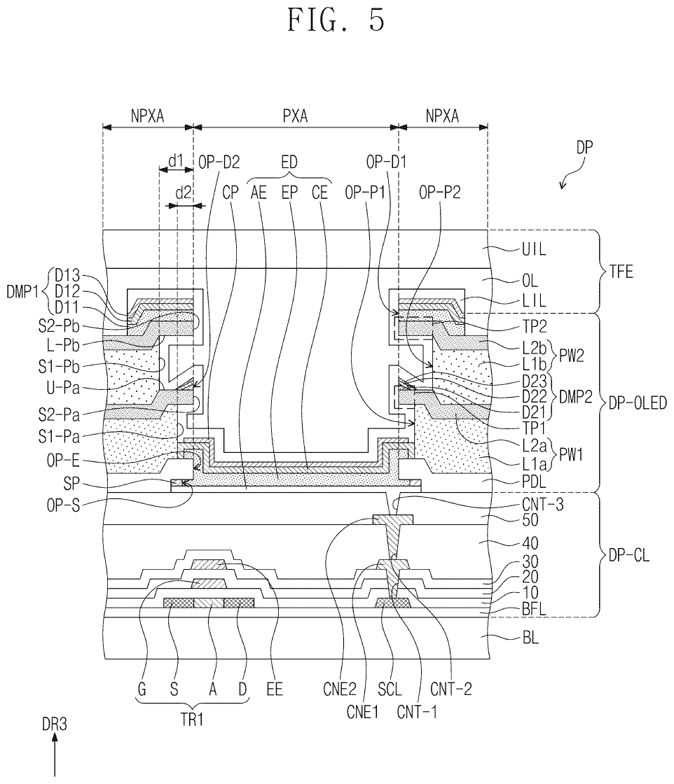

Referring to FIG. 4, the display region DA may include first to third light emitting regions PXA-R, PXA-G, and PXA-B and a peripheral region NPXA surrounding the first to third light emitting regions PXA-R, PXA-G, and PXA-B. The first to third light emitting regions PXA-R, PXA-G, and PXA-B may correspond to regions from which light is emitted, respectively, the light provided from light emitting elements ED1, ED2, and ED3 (see FIG. 5). The first to third light emitting regions PXA-R, PXA-G, and PXA-B may be distinguished according to the color of light emitted toward the outside of the display module DD (see FIG. 2).

The first to third light emitting regions PXA-R, PXA-G, and PXA-B may provide first to third color lights which have different colors from each other, respectively. In an embodiment, for example, the first color light may be red light, the second color light may be green light, and the third color light may be blue light. However, examples of the first to third color lights are not limited to the above examples.

Each of the first to third light emitting regions PXA-R, PXA-G, and PXA-B may be defined as a region in which an upper surface of an anode is exposed by a light emitting opening to be described later. The peripheral region NPXA sets boundaries of the first to third light emitting regions PXA-R, PXA-G, and PXA-B, and may prevent color mixing between the first to third pixel regions PXA-R, PXA-G, and PXA-B.

Each of the first to third light emitting regions PXA-R, PXA-G, and PXA-B is provided in plurality to be repeatedly disposed while having a predetermined arrangement form in the display region DA. In an embodiment, for example, the first and third light emitting regions PXA-R, PXA-G, and PXA-B may be alternately arranged along the first direction DR1 to form a ‘first group.’ The second light emitting regions PXA-G may be arranged along the first direction DR1 to form a ‘second group.’ The ‘first group’ and the ‘second group’ may each be provided in plurality, and the ‘first groups’ and the ‘second groups’ may be alternately arranged along the second direction DR2.

One second light emitting region PXA-G may be disposed spaced apart in a fourth direction DR4 from one first light emitting region PXA-R or one third light emitting region PXA-B. The fourth direction DR4 may be defined as a direction between the first and second directions DR1 and DR2.

FIG. 4 exemplarily illustrates an arrangement form of the first to third light emitting regions PXA-R, PXA-G, and PXA-B, but the first to third light emitting regions PXA-R, PXA-G, and PXA-B may be arranged in various forms without being limited thereto. In an embodiment, the first to third light emitting regions PXA-R, PXA-G, and PXA-B may have a PENTILE™ arrangement form as illustrated in FIG. 4. Alternatively, the first to third light emitting regions PXA-R, PXA-G, and PXA-B may have a Stripe arrangement form, or a Diamond Pixel™ arrangement form.

The first to third light emitting regions PXA-R, PXA-G, and PXA-B may have various shapes on a plane. In an embodiment, for example, the first to third light emitting regions PXA-R, PXA-G, and PXA-B may have shapes such as polygons, circles, ovals, or the like. FIG. 4 exemplarily illustrates the first and third light emitting regions PXA-R and PXA-B having a quadrangular shape (or a rhombic shape) on a plane and the second light emitting region PXA-G having an octagonal shape.

The first to third light emitting regions PXA-R, PXA-G, and PXA-B may have the same shape as each other on a plane, or at least some thereof may have different shapes from each other. FIG. 4 exemplarily illustrates the first and third light emitting regions PXA-R and PXA-B having the same shape as each other on a plane and the second pixel region PXA-G having a shape different from the shape of the first and third light emitting regions PXA-R and PXA-B.

At least some of the first to third light emitting regions PXA-R, PXA-G, and PXA-B have different areas from each other on a plane. In an embodiment, the area of the first light emitting region PXA-R which emits red light may be greater than the area of the second light emitting region PXA-G which emits green light, and may be less than the area of the third pixel region PXA-B which emits blue light. However, the relationship between large and small areas of the first to third light emitting regions PXA-R, PXA-G, and PXA-B according to the color of emitted light is not limited thereto, and may vary depending on the design of the display module DM (see FIG. 2) in another embodiment. Also, the embodiment of the invention is not limited thereto, and the first to third light emitting regions PXA-R, PXA-G, and PXA-B may have the same area as each other on a plane in another embodiment.

The shapes, areas, arrangements, and the like of the first to third light emitting regions PXA-R, PXA-G, and PXA-B of the display module DM (see FIG. 2) of the invention may be designed in various ways in accordance with the color of emitted light, or the shape and configuration of the display module DM (see FIG. 2), and are not limited to the embodiment illustrated in FIG. 4.

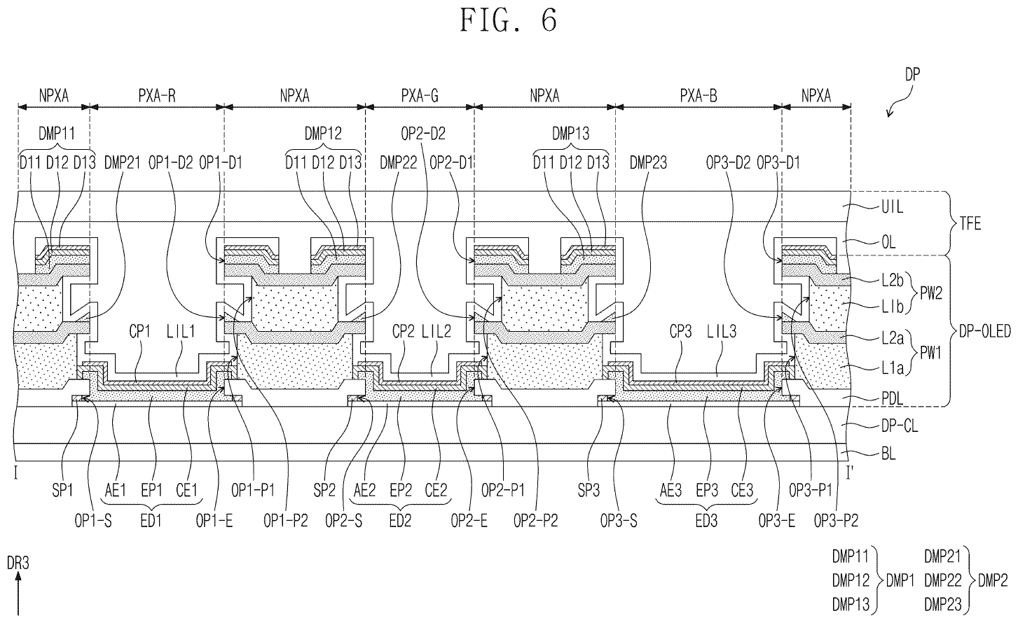

FIG. 5 is a cross-sectional view of an enlarged region of a display panel according to an embodiment of the invention. FIG. 6 is a cross-sectional view of a display panel according to an embodiment of the invention taken along line I-I′ of FIG. 4.

FIG. 5 illustrates an enlarged view of one light emitting region PXA in the display region DA (see FIG. 3), and the light emitting region PXA of FIG. 5 may correspond to any one of the first to third light emitting regions PXA-R, PXA-G, and PXA-B of FIG. 4. Referring to FIG. 5, a display panel DP may include a base layer BL, a circuit layer DP-CL, a display element layer DP-OLED, and an encapsulation layer TFE.

The display panel DP may include a plurality of insulation layers, a semiconductor pattern, a conductive pattern, a signal line, and the like. An insulation layer, a semiconductor layer, and a conductive layer are formed by coating, deposition, and/or the like. Thereafter, the insulation layer, the semiconductor layer, and the conductive layer may be selectively patterned by photolithography and etching. The semiconductor pattern, the conductive pattern, the signal line, and the like included in circuit element layer DP-CL and the display element layer DP-OLED may be formed in the above manner.

The circuit element layer DP-CL may be disposed on the base layer BL. The circuit element layer DP-CL may include a buffer layer BFL, a transistor TR1, a signal transmission region SCL, first to fifth insulation layers 10, 20, 30, 40, and 50, an electrode EE, and a plurality of connection electrodes CNE1 and CNE2.

The buffer layer BFL may be disposed on the base layer BL. The buffer layer BFL may improve the coupling force between the base layer BL and a semiconductor pattern. The buffer layer BFL may include a silicon oxide layer and a silicon nitride layer. The silicon oxide layer and the silicon nitride layer may be alternately stacked.

On the buffer layer BFL, a semiconductor pattern may be disposed. The semiconductor pattern may include polysilicon. However, the embodiment of the invention is not limited thereto, and the semiconductor pattern may include amorphous silicon, or a metal oxide in another embodiment. FIG. 5 only illustrates some semiconductor patterns, and a semiconductor pattern may be further disposed in the plurality of light emitting regions PXA-R, PXA-G, and PXA-B (see FIG. 4). The semiconductor pattern may be arranged according to a specific rule across the plurality of light emitting regions PXA-R, PXA-G, and PXA-B (see FIG. 4). The semiconductor pattern may have different electrical properties depending on whether or not the semiconductor pattern is doped. The semiconductor pattern may include a first region having a high doping concentration and a second region having a low doping concentration. The first region may be doped with an N-type dopant or a P-type dopant. The P-type transistor may include the first region doped with a P-type dopant.

The first region has a higher conductivity than the second region, and substantially serves as an electrode or signal line. The second region may substantially correspond to an active region (or a channel) of a transistor. In other words, a portion of a semiconductor pattern may be the active region of the transistor, another portion thereof may be a source or drain of the transistor, and the other portion thereof may be a conductive region.

A source S, an active region A, and a drain D of the transistor TR1 may be formed from a semiconductor pattern. FIG. 5 illustrates a portion of the signal transmission region SCL formed from the semiconductor pattern. Although not separately illustrated, the signal transmission region SCL may be connected to the drain D of the transistor TR1 on a plane.

The first to fifth insulation layers 10 to 50 may be disposed on the buffer layer BFL. The first to fifth insulation layers 10 to 50 may be an inorganic layer or organic layer.

The first insulation layer 10 may be disposed on the buffer layer BFL. A gate G of the transistor TR1 may be disposed on the first insulation layer 10. The second insulation layer 20 may be disposed on the first insulation layer 10 to cover the gate G. The electrode EE may be disposed on the second insulation layer 20.

The third insulation layer 30 may be disposed on the second insulation layer 20 to cover the electrode EE.

A first connection electrode CNE1 may be disposed on the third insulation layer 30. The first connection electrode CNE1 may be connected to the signal transmission region SCL through a contact hole CNT-1 passing through the first to third insulation layers 10 to 30. The fourth insulation layer 40 may be disposed on the third insulation layer 30 to cover the first connection electrode CNE1. The fourth insulation layer 40 may be an organic layer.

A second connection electrode CNE2 may be disposed on the fourth insulation layer 40. The second connection electrode CNE2 may be connected to the first connection electrode CNE1 through a contact hole CNT-2 passing through the fourth insulation layer 40. The fifth insulation layer 50 may be disposed on the fourth insulation layer 40 to cover the second connection electrode CNE2. The fifth insulation layer 50 may be an organic layer.

The display element layer DP-OLED may be disposed on the circuit element layer DP-CL. The display element layer DP-OLED may include a light emitting element ED, a pixel-definition layer PDL, a first partition wall PW1, a second partition wall PW2, a first dummy pattern DMP1, and a second dummy pattern DMP2.

The light emitting element ED may include an anode AE (or a first electrode), a light emitting pattern EP, and a cathode CE (or a second electrode). Each of the aforementioned first to third light emitting elements may include substantially the same components as components of the light emitting element ED of FIG. 5. Descriptions of the anode AE, the light emitting pattern EP, and the cathode E may be equally applied to an anode, a light emitting pattern, and a cathode of each of the first to third light emitting elements.

The anode AE may be disposed of the fifth insulation layer 50 of the circuit element layer DP-CL. The anode AE may be a transmissive electrode, a transflective electrode, or a reflective electrode. The anode AE may have conductivity. In an embodiment, for example, the anode AE may be formed of various materials, such as a metal, a transparent conductive oxide (“TCO”), or a conductive polymer material, as long as it has conductivity.

The anode AE may be connected to the second connection electrode CNE2 by a contact hole CNT-3 defined through the fifth insulation layer 50. Therefore, the anode AE may be electrically connected to the signal transmission region SCL through the first and second connection electrodes CNE1 and CNE2, and be electrically connected to a corresponding circuit element.

According to an embodiment of the invention, the display panel DP may further include a sacrificial pattern SP. The sacrificial pattern SP may be disposed on an upper surface the anode AE. In the sacrificial pattern SP, a sacrificial opening OP-S which exposes a portion of the upper surface of the anode AE may be defined. The sacrificial pattern SP may include an amorphous transparent conductive oxide.

The pixel-definition layer PDL may be disposed on the fifth insulation layer 50 of the circuit element layer DP-CL. A light emitting opening OP-E may be defined in the pixel-definition layer PDL. The light emitting opening OP-E may overlap the anode AE in a plan view, and the pixel-definition layer PDL may expose at least a portion of the anode AE through the light emitting opening OP-E.

In addition, the light emitting opening OP-E may overlap the sacrificial opening OP-S of the sacrificial pattern SP in a plan view. According to the present embodiment, the upper surface of the anode AE may be spaced apart from the pixel-definition layer PDL with the sacrificial pattern SP interposed therebetween in a cross-sectional view (or in the third direction DR3), and accordingly, it is possible to prevent the anode AE from being damaged in a process of forming the light emitting opening OP-E.

On a plane, the area of the light emitting opening OP-E may be smaller than the area of the sacrificial opening OP-S. That is, an inner surface of the pixel-definition layer PDL defining the light emitting opening OP-E may be more adjacent to the center of the anode AE than an inner surface of the sacrificial pattern SP defining the sacrificial opening OP-S. However, the embodiment of the invention is not limited thereto, and the inner surface of the sacrificial pattern SP defining the sacrificial opening OP-S may be substantially aligned with the inner surface of the pixel-definition layer PDL defining the light emitting opening OP-E in another embodiment. In this case, the light emitting region PXA may be viewed as a region of the anode AE, the region being exposed from a corresponding sacrificial opening OP-S. In another embodiment of the invention, the sacrificial pattern SP may be omitted.

The pixel-definition layer PDL may include an inorganic insulation material. In an embodiment, for example, the pixel-definition layer PDL may include a silicon nitride (SiNₓ). The pixel-definition layer PDL may be disposed between the anode AE and the first partition wall PW1 to prevent the anode AE and the first partition wall PW1 from being electrically connected to each other.

The first partition wall PW1 may be disposed on the pixel-definition layer PDL. The first partition wall PW1 may have a first partition-wall opening OP-P1 (or a lower partition-wall opening) defined therein. The first partition-wall opening OP-P1 may overlap the light emitting opening OP-E in a plan view, and may expose at least a portion of the anode AE.

The first partition wall PW1 may have an undercut shape in a cross-sectional view. The first partition wall PW1 may include a plurality of layers sequentially stacked, and at least one layer among the plurality of layers may be recessed compared to adjacent stacked layers of the first partition wall PW1. Accordingly, the first partition wall PW1 may include a first tip portion TP1.

In the present embodiment, the first partition wall PW1 may include a first lower layer L1a and a second lower layer L2a. The first lower layer L1a may be disposed on the pixel-definition layer PDL, and the second lower layer L2a may be disposed on the first lower layer L1a. The first lower layer L1a may have a first conductivity, and the second lower layer L2a may have a second conductivity which is lower than the first conductivity. The thickness of the first lower layer L1a may be greater than the thickness of the second lower layer L2a.

In the present embodiment, the first lower layer L1a may be relatively recessed compared to the second lower layer L2a with respect to the light emitting region PXA. That is, the first lower layer L1a may be formed by being undercut with respect to the second lower layer L2a. A portion of the second lower layer L2a protruding from the first lower layer L1a toward the light emitting region PXA may define the first tip portion TP1.

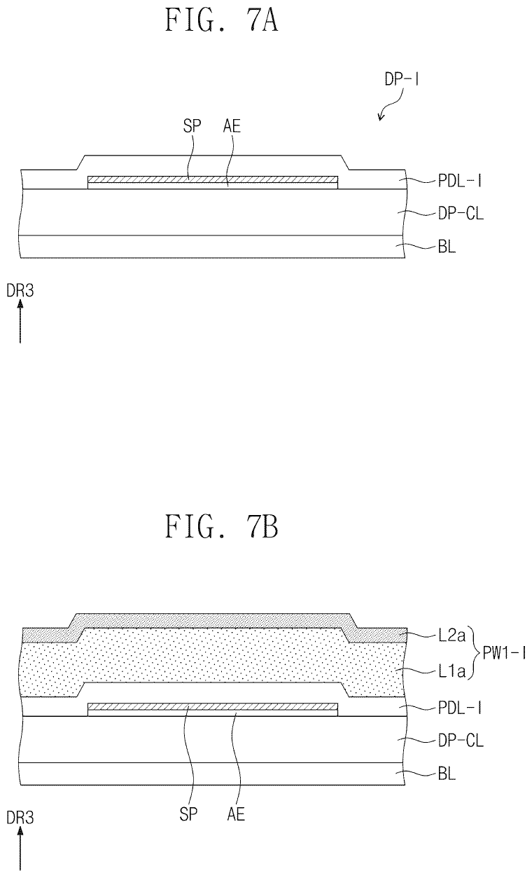

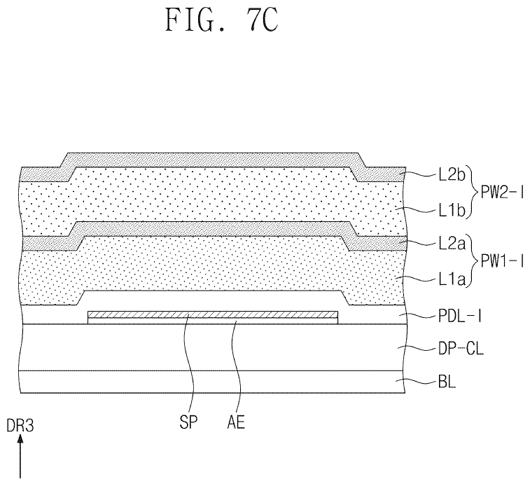

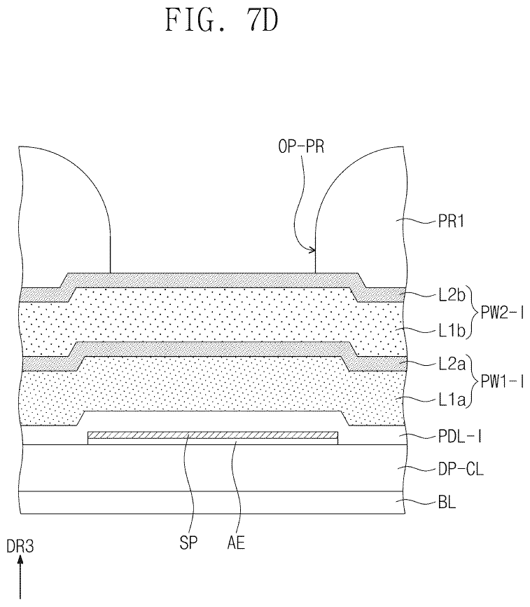

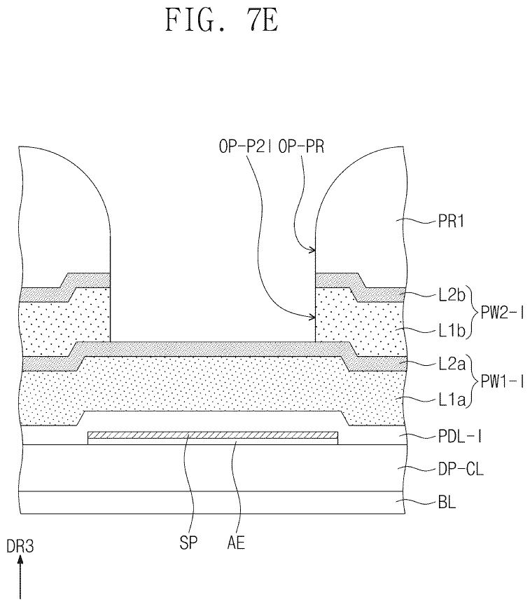

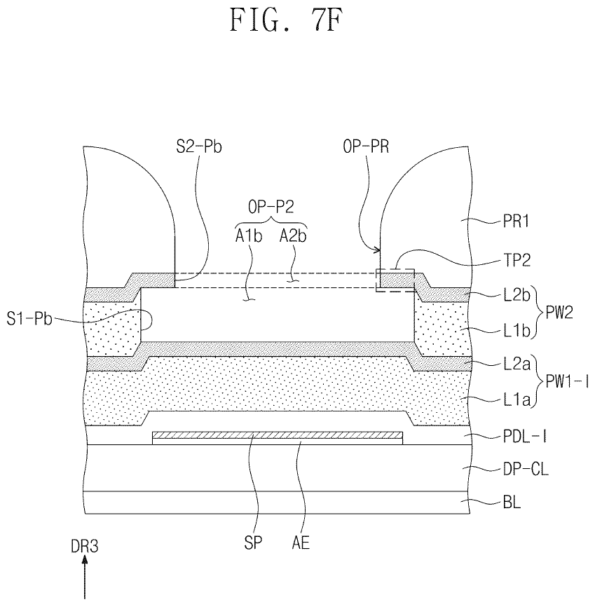

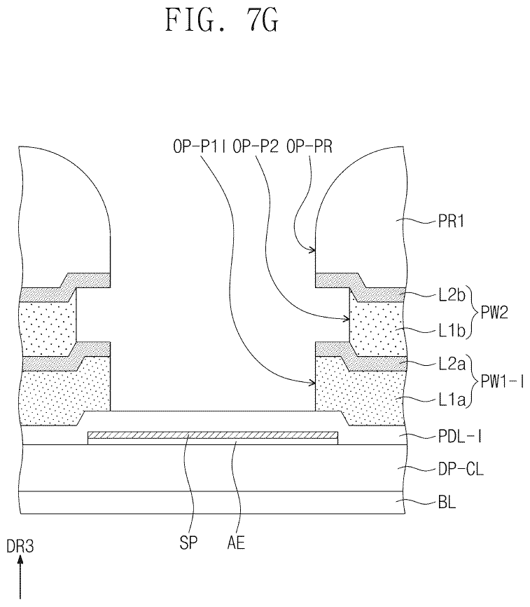

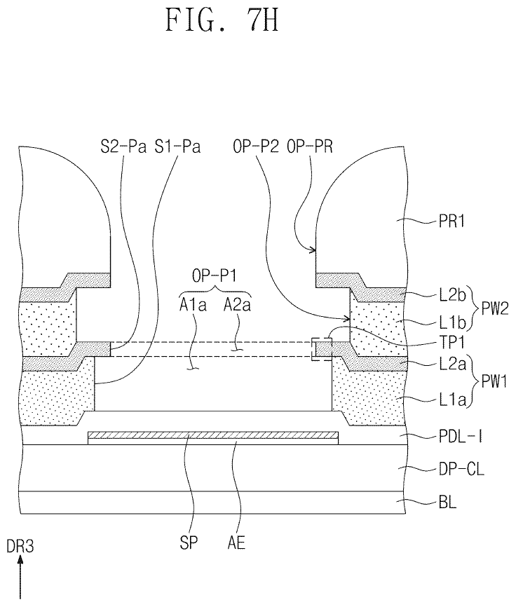

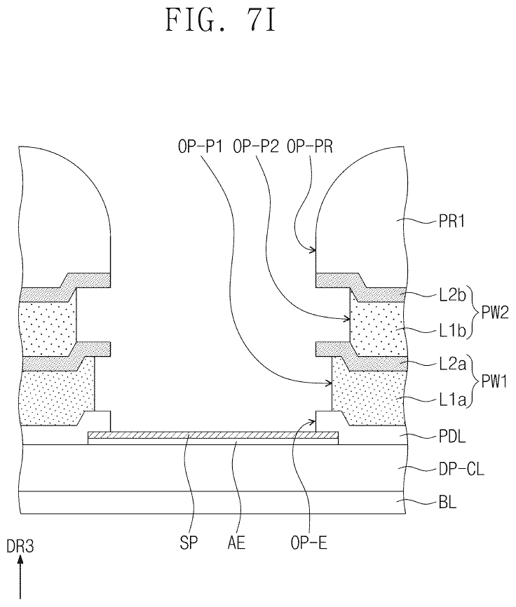

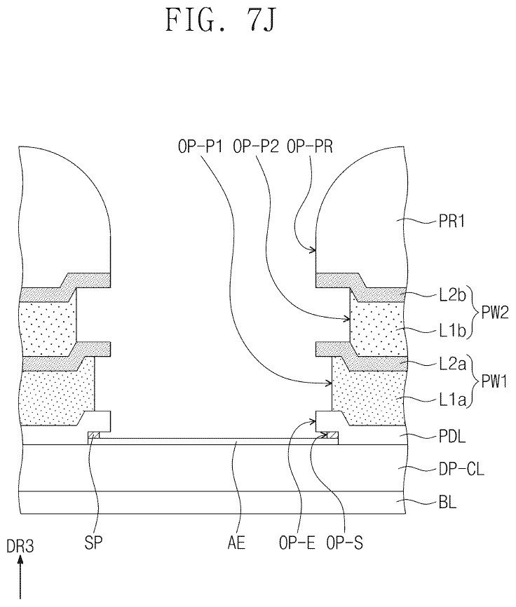

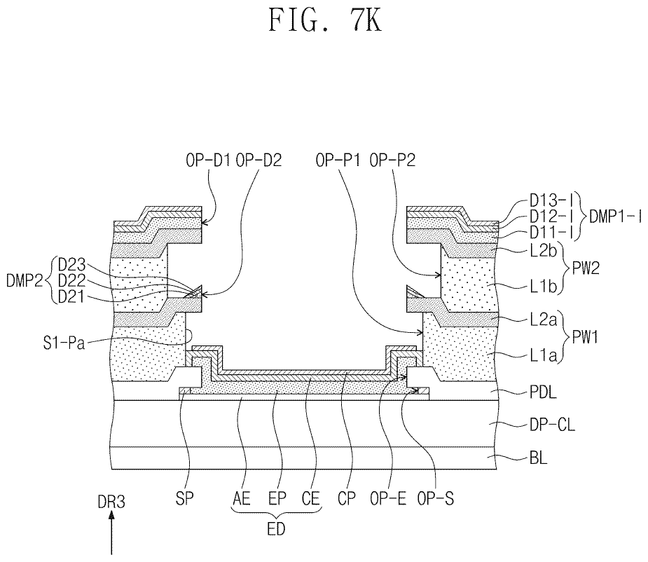

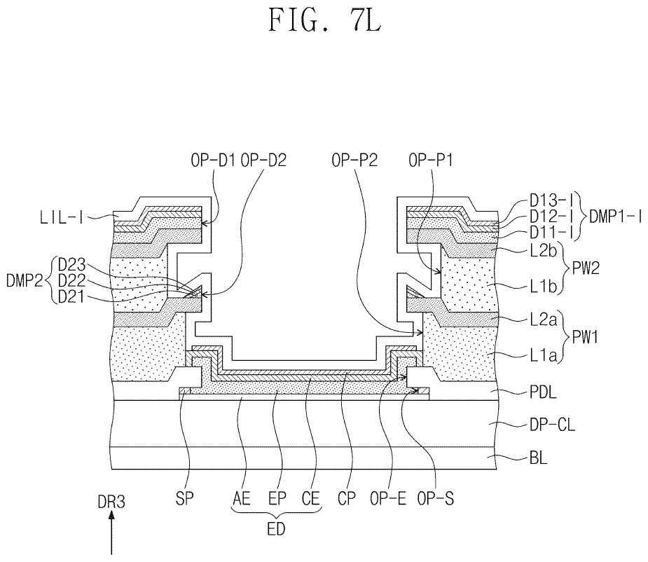

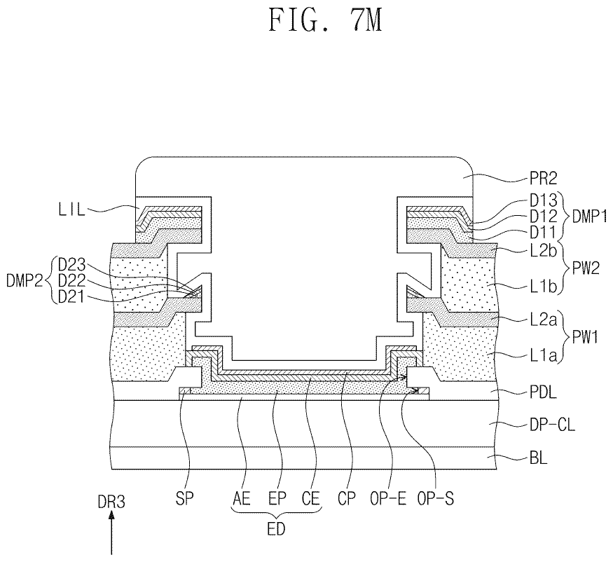

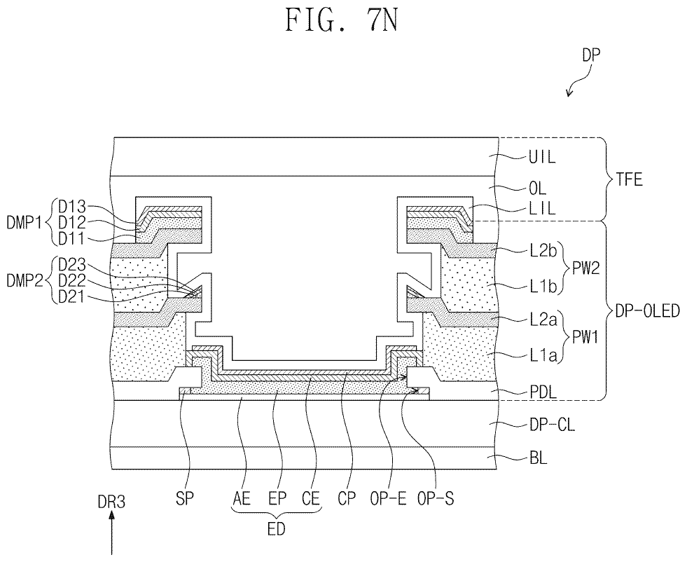

The first partition-wall opening OP-P1 defined in the first partition wall PW1 may include a first lower region Ala (see FIG. 7H) and a second lower region A2a (see FIG. 7H) sequentially arranged in the third direction DR3. The first lower layer L1a may include a first lower inner surface S1-Pa defining the first lower region Ala (see FIG. 7H) of the first partition-wall opening OP-P1, and the second lower layer L2a may include a second lower inner surface S2-Pa defining the second lower region A2a (see FIG. 7H) of the first partition-wall opening OP-P1. The first lower inner surface S1-Pa of the first lower layer L1a may be recessed and disposed in a direction farther away from the light emitting opening OP-E (or the light emitting region PXA defined by the light emitting opening OP-E) than the second lower inner surface S2-Pa of the second lower layer L2a. That is, the first lower inner surface S1-Pa may be formed by being undercut with respect to the second lower inner surface S2-Pa.

Each of the first lower layer L1a and the second lower layer L2a may include a conductive material.

In the present embodiment, the first lower layer L1a may include a metal. In an embodiment, for example, the first lower layer L1a may include at least one of aluminum (Al) or molybdenum (Mo). However, the material of the first lower layer L1a is not limited thereto.

In the present embodiment, the second lower layer L2a may include at least one of a metal or a metal nitride. In an embodiment, for example, the second lower layer L2a may include at least one of tungsten (W), molybdenum (Mo), a titanium nitride (TiNₓ), or an aluminum nitride (AlNₓ). In this case, the second lower layer L2a may have a greater modulus value than when the second lower layer L2a includes titanium (Ti), and accordingly, it is possible to reduce or prevent the bending of the first tip portion TP1 defined in the second lower layer L2a. However, the material of the second lower layer L2a is not limited thereto.

FIG. 5 exemplarily illustrates that each of the first and second lower inner surfaces S1-Pa and S2-Pa is perpendicular to an upper surface of the pixel-definition layer PDL, but the embodiment of the invention is not limited thereto, and the first partition wall PW1 may have a tapered shape, or a reverse tapered shape in another embodiment.

The light emitting pattern EP may be disposed on the anode AE. The light emitting pattern EP may be patterned by the first tip portion TP1 defined in the first partition wall PW1. At least a portion of the light emitting pattern EP may be disposed in the light emitting opening OP-E and the first partition-wall opening OP-P1. In an embodiment including the sacrificial pattern SP, the light emitting pattern EP may also be disposed in the sacrificial opening OP-S. The light emitting pattern EP may cover a portion of the upper surface of the pixel-definition layer PDL exposed from the first partition-wall opening OP-P1.

The light emitting pattern EP may include a light emitting layer including a light emitting material. The light emitting pattern EP may further include a hole injection layer and a hole transport layer disposed between the anode AE and the light emitting layer, or may further include an electron transport layer and an electron injection layer disposed on the light emitting layer. The light emitting pattern EP may also be referred to as an ‘organic layer’ or an ‘intermediate layer.’

The cathode CE may be disposed on the light emitting pattern EP. The cathode CE may be patterned by the first tip portion TP1 defined in the first partition wall PW1. At least a portion of the cathode CE may be disposed in the first partition-wall opening OP-P1. In an embodiment of the invention, depending on the thickness of the light emitting pattern EP or the thickness of the pixel-definition layer PDL, a portion of the cathode CE may also be disposed in the light emitting opening OP-E.

The cathode CE may be in contact with the first lower inner surface S1-Pa of the first lower layer L1a. The cathode CE may have conductivity. In an embodiment, for example, the cathode CE may be formed of various materials, such as a metal, a transparent conductive oxide (TCO), or a conductive polymer material, as long as it has conductivity.

In the present embodiment, the first partition wall PW1 may receive a bias voltage. The cathode CE may be electrically connected to the first partition wall PW1, and be provided with the bias voltage.

FIG. 5 exemplarily illustrates that the light emitting pattern EP is not in contact with the first lower inner surface S1-Pa of the first lower layer L1a, but the embodiment of the invention is not limited thereto, and the light emitting pattern EP may also be formed to be in contact with the first lower inner surface S1-Pa of the first lower layer L1a together with the cathode CE in another embodiment.

According to an embodiment of the invention, the display panel DP may further include a capping pattern CP. The capping pattern CP may be disposed on the cathode CE, and at least a portion of the capping pattern CP may be disposed in the first partition-wall opening OP-P1. The capping pattern CP may be patterned by the first tip portion TP1 formed in the first partition wall PW1.

FIG. 5 exemplarily illustrates that the capping pattern CP is not in contact with the first lower inner surface S1-Pa of the first lower layer L1a, but the embodiment of the invention is not limited thereto, and the capping pattern EP may be formed to be in contact with the first lower inner surface S1-Pa of the first lower layer L1a in another embodiment. According to another embodiment of the invention, the capping pattern CP may be omitted.

The second partition wall PW2 may be disposed on the first partition wall PW1. The second partition wall PW2 may have a second partition-wall opening OP-P2 (or an upper partition-wall opening) defined therein. The second partition-wall opening OP-P2 may overlap the light emitting opening OP-E and the first partition-wall opening OP-P1 in a plan view, and may expose at least a portion of the anode AE.

The second partition wall PW2 may have an undercut shape in a cross-sectional view. The second partition wall PW2 may include a plurality of layers sequentially stacked, and at least one layer among the plurality of layers may be recessed compared to adjacent stacked layers of the second partition wall PW2. Accordingly, the second partition wall PW2 may include a second tip portion TP2.

In the present embodiment, the second partition wall PW2 may include a first upper layer L1b and a second upper layer L2b. The first upper layer L1b may be disposed on the first partition wall PW1, and the second upper layer L2b may be disposed on the first upper layer L1b. The thickness of the first upper layer Lib may be greater than the thickness of the second upper layer L2b.

In the present embodiment, the first upper layer L1b may be relatively recessed compared to the second upper layer L2b with respect to the light emitting region PXA. That is, the first upper layer L1b may be formed by being undercut with respect to the second upper layer L2b. A portion of the second upper layer L2b protruding from the first upper layer L1b toward the light emitting region PXA may define the second tip portion TP2.

The second partition-wall opening OP-P2 defined in the second partition wall PW2 may include a first upper region A1b (see FIG. 7F) and a second upper region A2b (see FIG. 7F) sequentially arranged in the third direction DR3. The first upper layer L1b may include a first upper inner surface S1-Pb defining the first upper region A1b (see FIG. 7F) of the second partition-wall opening OP-P2, and the second upper layer L2b may include a second upper inner surface S2-Pb defining the second upper region A2b (see FIG. 7F) of the second partition-wall opening OP-P2. The first upper inner surface S1-Pb of the first upper layer L1b may be recessed and disposed in a direction farther away from the light emitting opening OP-E (or the light emitting region PXA defined by the light emitting opening OP-E) than the second upper inner surface S2-Pb of the second upper layer L2b. That is, the first upper inner surface S1-Pb may be formed by being undercut with respect to the second upper inner surface S2-Pb.

In the present embodiment, a width d1 in which the first upper inner surface S1-Pb is recessed from the second lower inner surface S2-Pa may be greater than or equal to a width d2 in which the first lower inner surface S1-Pa is recessed from the second lower inner surface S2-Pa. That is, the degree to which the first upper layer L1b is recessed from the second lower layer L2a may be greater than or equal to the degree to which the first lower layer L1a is recessed from the second lower layer L2a.

The first upper layer L1b may include an inorganic material. In an embodiment, for example, the first upper layer L1b may include at least one of silicon nitride (SiNₓ), silicon oxide (SiO₂), silicon oxynitride (SiON), or aluminum oxide (Al₂O₃). However, the material of the first upper layer L1b is not limited thereto. According to the present embodiment, since the first upper layer L1b includes an inorganic material, interfacial adhesion with a lower encapsulation inorganic pattern LIL (or an “encapsulation inorganic pattern”) may be increased, and moisture may be effectively prevented from penetrating into the light emitting element ED. A detailed description thereof will be described later along with a description of the lower encapsulation inorganic pattern LIL.

The second upper layer L2b may include a conductive material. In the present embodiment, the second upper layer L2b may include a metal material or a metal nitride. In an embodiment, for example, the second upper layer L2b may include at least one of tungsten (W), molybdenum (Mo), a titanium nitride (TiNₓ), or an aluminum nitride (AlNₓ). In this case, the second upper layer L2b may have a greater modulus value than when the second upper layer L2b includes titanium (Ti), and accordingly, it is possible to reduce or prevent the bending of the second tip portion TP2 defined in the second upper layer L2b. However, the material of the second upper layer L2b is not limited thereto. In another embodiment, the second upper layer L2b and the second lower layer L2a may include the same material.

FIG. 5 exemplarily illustrates that each of the first and second upper inner surfaces S1-Pb and S2-Pb is perpendicular to the upper surface of the pixel-definition layer PDL, but the embodiment of the invention is not limited thereto, and the second partition wall PW2 may have a tapered shape, or a reverse tapered shape in another embodiment.

The first dummy pattern DMP1 may be disposed on the second partition wall PW2. The first dummy pattern DMP1 may include a 1-1 dummy layer D11, a 1-2 dummy layer D12, and a 1-3 dummy layer D13. The 1-1 to 1-3 dummy layers D11, D12, and D13 may be sequentially stacked along the third direction DR3 on an upper surface of the second upper layer L2b.

The second dummy pattern DMP2 may be disposed on an upper surface U-Pa of the second lower layer L2a exposed from the first upper layer L1b. The second dummy pattern DMP2 may include a 2-1 dummy layer D21, a 2-2 dummy layer D22, and a 2-3 dummy layer D23. The 2-1 to 2-3 dummy layers D21, D22, and D23 may be sequentially stacked along the third direction DR3 on the upper surface U-Pa of the second lower layer L2a.

The 1-1 dummy layer D11 and the 2-1 dummy layer D21 may include an organic material. In an embodiment, for example, the 1-1 dummy layer D11 and the 2-1 dummy layer D21 may include a material the same as the material of the light emitting pattern EP. The 1-1 dummy layer D11 and the 2-1 dummy layer D21 may be simultaneously formed with the light emitting pattern EP through one process, and may be formed by being separated from the light emitting pattern EP by the undercut shape of the first and second partition walls PW1 and PW2.

The 1-2 dummy layer D12 and the 2-2 dummy layer D22 may include a conductive material. In an embodiment, for example, the 1-2 dummy layer D12 and the 2-2 dummy layer D22 may include a material the same as the material of the cathode CE. The 1-2 dummy layer D12 and the 2-2 dummy layer D22 may be simultaneously formed with the cathode CE through one process, and may be formed by being separated from the cathode CE by the undercut shape of the first and second partition walls PW1 and PW2.

The 1-3 dummy layer D13 and the 2-3 dummy layer D23 may include a material the same as the material of the capping pattern CP. The 1-3 dummy layer D13 and the 2-3 dummy layer D23 may be simultaneously formed with the capping pattern CP through one process, and may be formed by being separated from the capping pattern CP by the undercut shape of the first and second partition walls PW1 and PW2.

In the first dummy pattern DMP1, a first dummy opening OP-D1 may be defined. The first dummy opening OP-D1 may overlap the light emitting opening OP-E in a plan view. The first dummy opening OP-D1 may be defined by inner surfaces of the 1-1 to 1-3 dummy layers D11, D12, and D13. On a plane, the first dummy pattern DMP1 may have a closed-line shape surrounding the light emitting region PXA.

FIG. 5 exemplarily illustrates that the inner surfaces of the 1-1 to 1-3 dummy layers D11, D12, and D13 defining the first dummy opening OP-D1 are aligned with the second upper inner surface S2-Pb of the second upper layer L2b, but the embodiment of the invention is not limited thereto, and the 1-1 to 1-3 dummy layers D11, D12, and D13 may cover the second upper inner surface S2-Pb of the second upper layer L2b in another embodiment.

In the second dummy pattern DMP2, a second dummy opening OP-D2 may be defined. The second dummy opening OP-D2 may overlap with the light emitting opening OP-E in a plan view. The second dummy opening OP-D2 may be defined by inner surfaces of the 2-1 to 2-3 dummy layers D21, D22, and D23. On a plane, the second dummy pattern DMP2 may have a closed-line shape surrounding the light emitting region PXA.

The encapsulation layer TFE may be disposed on the display element layer DP-OLED. The encapsulation layer TFE may include the lower encapsulation inorganic pattern LIL (or an inorganic pattern), an encapsulation organic film OL, and an upper encapsulation inorganic film UIL.

The lower encapsulation inorganic pattern LIL may cover the light emitting element ED. Specifically, the lower encapsulation inorganic pattern LIL may be disposed on the cathode CE to cover the cathode CE, and in an embodiment, the capping pattern CP disposed on the cathode CE may be covered together.

A portion of the lower encapsulation inorganic pattern LIL may be disposed in the light emitting opening OP-E, the first partition-wall opening OP-P1, and the second partition-wall opening OP-P2. In another embodiment of the invention, depending on the thickness of the light emitting pattern EP, the cathode CE, and the capping pattern CP or the thickness of the pixel-definition layer PDL, the lower encapsulation inorganic pattern LIL may not be disposed in the light emitting opening OP-E.

The lower encapsulation inorganic pattern LIL may be in contact with the first and second lower inner surfaces S1-Pa and S2-Pa of the first partition wall PW1 defining the first partition-wall opening OP-P1 and the first and second upper inner surfaces S1-Pb and S2-Pb of the second partition wall PW2 defining the second partition-wall opening OP-P2, and may cover the first and second lower inner surfaces S1-Pa and S2-Pa and the first and second upper inner surfaces S1-Pb and S2-Pb. Specifically, a portion of the first lower inner surface S1-Pa not in contact with the cathode may be covered by the lower encapsulation inorganic pattern LIL.

The lower encapsulation inorganic pattern LIL is exposed from the first upper layer L1b and may cover a lower surface L-Pb of the second upper layer L2b connected to the second upper inner surface S2-Pb. The lower encapsulation inorganic pattern LIL may cover the upper surface U-Pa of the second lower layer L2a exposed from the first upper layer L1b, and the second dummy pattern DMP2.

In addition, another portion of the lower encapsulation inorganic pattern LIL is disposed on the second partition wall PW2, and may cover a portion of the first dummy pattern DMP1. The lower encapsulation inorganic pattern LIL may be in contact with inner surfaces of the first dummy pattern DMP1 defining the first dummy opening OP-D1.

According to the present embodiment, the first upper layer L1b is recessed from each of the second lower layer L2a and the second upper layer L2b, so that the lower encapsulation inorganic pattern LIL may be in contact with a portion of the lower surface L-Pb of the second upper layer L2b and a portion of the upper surface U-Pa of the second lower layer L2a. As the lower encapsulation inorganic pattern LIL becomes more in contact with the first partition wall PW1 and the second partition wall PW2, even when moisture penetrates between the lower encapsulation inorganic pattern LIL and the first dummy pattern DMP1 or between the lower encapsulation inorganic pattern LIL and the second partition wall PW2, a path through which the penetrated moisture moves along the first and second partition walls PW1 and PW2 to a portion of which the light emitting element ED is disposed may be lengthened, so that it is possible to effectively prevent the moisture from penetrating into the light emitting element ED.

In the present embodiment, the lower encapsulation inorganic pattern LIL may include an inorganic material. In an embodiment, for example, the lower encapsulation inorganic pattern LIL may include a silicon nitride (SiNₓ). According to the present embodiment, since the lower encapsulation inorganic pattern LIL and the first upper layer L1b each include an inorganic material, the lower encapsulation inorganic pattern LIL and the first upper inner surface S1-Pb of the first upper layer L1b may be in contact with a high interfacial adhesion. Therefore, it is possible to effectively reduce or prevent a phenomenon in which the lower encapsulation inorganic pattern LIL is separated from the second partition wall PW2 during a process. Through the above, it is possible to effectively reduce or prevent moisture from penetrating between the lower encapsulation inorganic pattern LIL and the second partition wall PW2. In addition, even when moisture penetrates between the lower encapsulation inorganic pattern LIL and the second upper layer L2b, the penetrated moisture may be prevented from moving along the first upper inner surface S1-Pb to prevent a moisture permeation path from forming towards the light emitting element ED.

According to an embodiment of the invention, the lower encapsulation inorganic pattern LIL may include a material the same as the material of the first upper layer L1b. In this case, interfacial adhesion between the lower encapsulation inorganic pattern LIL and the first upper layer L1b may be maximized, so that it is possible to stop moisture from penetrating or penetrated moisture from moving along the first upper inner surface S1-Pb.

The encapsulation organic film OL covers the lower encapsulation inorganic pattern LIL, and may provide a flat upper surface. The upper encapsulation inorganic film UIL may be disposed on the encapsulation organic film OL.

The lower encapsulation inorganic pattern LIL and the upper encapsulation inorganic film UIL may protect the display element layer DP-OLED from moisture/oxygen, and the encapsulation organic film OL may protect the display element layer DP-OLED from foreign substances such as dust particles.

FIG. 6 illustrates an enlarged view of one first light emitting region PXA-R, one second light emitting region PXA-G, and one third light emitting region PXA-B, and the description of one light emitting region PXA of FIG. 5 may be equally applied to each of the first to third light emitting regions PXA-R, PXA-G, and PXA-B.

Referring to FIG. 6, a display panel DP according to the present embodiment may include a base layer BL, a circuit layer DP-CL, a display element layer DP-OLED, and an encapsulation layer TFE. The display element layer DP-OLED may include light emitting elements ED1, ED2, and ED3, sacrificial patterns SP1, SP2, and SP3, a pixel-definition layer PDL, a first partition wall PW1, a second partition wall PW2, a first dummy pattern DMP1, and a second dummy pattern DMP2. FIG. 6 schematically illustrates the circuit element layer DP-CL, and the description of the circuit element layer DP-CL of FIG. 5 may be equally applied thereto.

The light emitting elements ED1, ED2, and ED3 may include a first light emitting element ED1, a second light emitting element ED2, and a third light emitting element ED3.

The first light emitting element ED1 may include a first anode AE1, a first light emitting pattern EP1, and a first cathode CE1, the second light emitting element ED2 may include a second anode AE2, a second light emitting pattern EP2, and a second cathode CE2, and the third light emitting element ED3 may include a third anode AE3, a third light emitting pattern EP3, and a third cathode CE3. The first to third anodes AE1, AE2, and AE3 may be provided as a plurality of patterns. In an embodiment, the first light emitting pattern EP1 may provide red light, the second light emitting pattern EP2 may provide green light, and the third light emitting pattern EP3 may provide blue light.

In the present embodiment, in the pixel-definition layer PDL, first to third light emitting openings OP1-E, OP2-E, and OP3-E may be defined.

The first light emitting opening OP1-E may expose at least a portion of the first anode AE1. The first light emitting region PXA-R may be defined as a region of an upper surface of the first anode AE1 that is exposed by the first light emitting opening OP1-E. The second light emitting opening OP2-E may expose at least a portion of the second anode AE2. The second light emitting region PXA-G may be defined as a region of an upper surface of the second anode AE2 that is exposed by the second light emitting opening OP2-E. The third light emitting opening OP3-E may expose at least a portion of the third anode AE3. The third light emitting region PXA-B may be defined as a region of an upper surface of the third anode AE3 that is exposed by the third light emitting opening OP3-E.

In the present embodiment, the sacrificial patterns SP1, SP2, and SP3 may include a first sacrificial pattern SP1, a second sacrificial pattern SP2, and a third sacrificial pattern SP3. The first to third sacrificial patterns SP1, SP2, and SP3 may be disposed on upper surfaces of the first to third anodes AE1, AE2, and AE3, respectively. In the first to third sacrificial patterns SP1, SP2, and SP3, first to third sacrificial openings OP1-E, OP2-E, and OP3-E overlapping the first to third light emitting openings OP1-E, OP2-E, and OP3-E in a plan view, respectively, may be defined.

In the present embodiment, in the first partition wall PW1, 1-1, 1-2, and 1-3 partition-wall openings OP1-P1, OP2-P1, and OP3-P1 overlapping the first to third light emitting openings OP1-E, OP2-E, and OP3-E in a plan view, respectively, may be defined. The first partition-wall opening OP-P1 described above with reference to FIG. 5 may correspond to any one of the 1-1, 1-2, and 1-3 partition-wall openings OP1-P1, OP2-P1, and OP3-P1, and to each of the 1-1, 1-2, and 1-3 partition-wall openings OP1-P1, OP2-P1, and OP3-P1, the description of the first partition-wall opening OP-P1 described above with reference to FIG. 5 may be equally applied. Each of the 1-1 to 1-3 partition-wall openings OP1-P1, OP2-P1, and OP3-P1 may include the first lower region Ala (see FIG. 7H) and the second lower region A2a (see FIG. 7H) described above with reference to FIG. 5.

The first lower layer L1a may include the first lower inner surfaces S1-Pa (see FIG. 5) defining the first lower regions Ala (see FIG. 7H) of the 1-1 to 1-3 partition-wall openings OP1-P1, OP2-P1, and OP3-P1, respectively, and the second lower layer L2a may include the second lower inner surfaces S2-Pa (see FIG. 5) defining the second lower region A2a (see FIG. 7H) of the 1-1 to 1-3 partition-wall openings OP1-P1, OP2-P1, and OP3-P1, respectively.

The first light emitting pattern EP1 and the first cathode CE1 may be disposed in the first light emitting opening OP1-E and the 1-1 partition-wall opening OP1-P1, the second light emitting pattern EP2 and the second cathode CE2 may be disposed in the second light emitting opening OP2-E and the 1-2 partition-wall opening OP2-P1, and the third light emitting pattern EP3 and the third cathode CE3 may be disposed in the third light emitting opening OP3-E and the 1-3 partition-wall opening OP3-P1. The first to third cathodes CE1, CE2, and CE3 may be in contact with the first lower inner surfaces S1-Pa (see FIG. 5) of the first lower layer L1a, respectively.

In the present embodiment, the first to third cathodes CE1, CE2, and CE3 may be physically separated by the second lower layer L2a forming the first tip portion TP1 (see FIG. 5), and be electrically connected to each other by being in contact with the first lower layer L1a in the first partition-wall opening OP1-P1, OP2-P1, and OP3-P1, respectively, to be provided with a common voltage. The first lower layer L1a has a relatively high electrical conductivity and a large thickness compared to the second lower layer L2a, and thus may reduce contact resistance with the first to third cathodes CE1, CE2, and CE3. Accordingly, a common cathode voltage may be uniformly provided to the light emitting regions PXA-R, PXA-G, and PXA-B.

According to the invention, a plurality of first light emitting patterns EP1 may be patterned and deposited in units of pixels by the first tip portion TP1 (see FIG. 5) defined in the first partition wall PW1. That is, the first light emitting patterns EP1 are commonly formed using an open mask, but may be easily divided into units of pixels by the first partition wall PW1.

On the other hand, when the first light emitting patterns EP1 are patterned using a fine metal mask (“FMM”), a support spacer protruding from a partition wall should be provided to support the fine metal mask. In addition, since the fine metal mask is spaced apart from a base surface on which patterning is performed by the height of the partition wall and the height of the spacer, there may be a limitation in the implementation of a high resolution. In addition, since the fine metal mask is in contact with the spacer, foreign substances may remain in the spacer after the patterning process of the first light emitting patterns EP1, or the spacer may be damaged by an imprint of the fine metal mask. Accordingly, a defective display panel may be provided.

According to the present embodiment, by including the first partition wall PW1, physical separation between the light emitting elements ED1, ED2, and ED3 may be facilitated. Accordingly, current leakage or driving error between adjacent light emitting regions PXA-R, PXA-G, and PXA-B may be effectively prevented, and independent driving may be possible for each of the light emitting element ED1, ED2, and ED3.

Particularly, by patterning the plurality of first light emitting patterns EP1 without a mask that is in contact with interior components inside the display region DA (see FIG. 2), it is possible to provide a display panel DP with improved process reliability due to a decreased defect rate. Since patterning may be performed even when a separate support spacer protruding from the second partition wall PW2 is not provided, the area of the light emitting regions PXA-R, PXA-G, and PXA-B may be refined, so that it is possible to provide a display panel DP with easy implementation of a high resolution.

In addition, in manufacturing a large-area display panel DP, the process cost may be reduced by omitting the production of a large-area mask, and since there is no influence of defects that may be generated in a large-area mask, it is possible to provide the display panel DP with improved process reliability.

In the present embodiment, capping patterns CP1, CP2, and CP3 may include a first capping pattern CP1, a second capping pattern CP2, and a third capping pattern CP3. The first to third capping patterns CP1, CP2, and CP3 may be disposed on the first to third cathodes CE1, CE2, and CE3, and may be disposed in the first to third light emitting openings OP1-E, OP2-E, and OP3-E and the 1-1 to 1-3 partition-wall openings OP1-P1, OP2-P1, and OP3-P1, respectively.

In the present embodiment, in the second partition wall PW2, 2-1, 2-2, and 2-3 partition-wall openings OP1-P2, OP2-P2, and OP3-P2 overlapping the first to third light emitting openings OP1-E, OP2-E, and OP3-E and the 1-1, 1-2, and 1-3 partition-wall openings OP1-P1, OP2-P1, and OP3-P1 in a plan view, respectively, may be defined. The second partition-wall opening OP-P2 described above with reference to FIG. 5 may correspond to any one of the 2-1, 2-2, and 2-3 partition-wall openings OP1-P2, OP2-P2, OP3-P2, and to each of the 2-1, 2-2, and 2-3 partition-wall openings OP1-P2, OP2-P2, OP3-P2, the description of the second partition-wall opening OP-P2 described above with reference to FIG. 5 may be equally applied. Each of the 2-1 to 2-3 partition-wall openings OP1-P2, OP2-P2, and OP3-P2 may include the first upper region A1b (see FIG. 7F) and the second upper region A2b (see FIG. 7F) described above with reference to FIG. 5.

The first upper layer L1b may include the first upper inner surfaces S1-Pb (see FIG. 5) defining the first upper regions A1b (see FIG. 7F) of the 2-1 to 2-3 partition-wall openings OP1-P2, OP2-P2, and OP3-P2, respectively, and the second upper layer L2b may include the second upper inner surfaces S2-Pb (see FIG. 5) defining the second upper region A2b (see FIG. 7F) of the 2-1 to 2-3 partition-wall openings OP1-P2, OP2-P2, and OP3-P2, respectively.

In the present embodiment, the first dummy patterns DMP1 may include a 1-1 dummy pattern DMP11, a 1-2 dummy pattern DMP12, and a 1-3 dummy pattern DMP13. The 1-1 to 1-3 dummy patterns DMP11, DMP12, and DMP13 may surround the first to third light emitting regions PXA-R, PXA-G, and PXA-B on a plane, respectively. The 1-1 to 1-3 dummy patterns DMP11, DMP12, and DMP13 may include a 1-1 dummy layer D11, a 1-2 dummy layer D12, and a 1-3 dummy layer D13, respectively, and to the 1-1 to 1-3 dummy layers D11, D12, and D13 (see FIG. 5) of the respective 1-1 to 1-3 dummy patterns DMP11, DMP12, and DMP13, the description of the first to third dummy layers D11, D22, and D23 described above with reference to FIG. 5 may be equally applied.

In the 1-1 to 1-3 dummy patterns DMP11, DMP12, and DMP13, 1-1, 1-2, and 1-3 dummy openings OP1-D1, OP2-D1, and OP3-D1 overlapping the first, second, and third light emitting openings OP1-E, OP2-E, and OP3-E in a plan view, respectively, may be defined. The 1-1 dummy opening OP1-D1 may be defined by inner surfaces of the 1-1 to 1-3 dummy layers D11, D12, and D13 of the 1-1 dummy pattern DMP11. The 1-2 dummy opening OP2-D1 may be defined by inner surfaces of the 1-1 to 1-3 dummy layers D11, D12, and D13 of the 1-2 dummy pattern DMP12. The 1-3 dummy opening OP3-D1 may be defined by inner surfaces of the 1-1 to 1-3 dummy layers D11, D12, and D13 of the 1-3 dummy pattern DMP13.

In the present embodiment, the second dummy pattern DMP2 may include a 2-1 dummy pattern DMP21, a 2-2 dummy pattern DMP22, and a 2-3 dummy pattern DMP23. The 2-1 to 2-3 dummy patterns DMP21, DMP22, and DMP23 may surround the first to third light emitting regions PXA-R, PXA-G, and PXA-B on a plane, respectively. FIG. 6 illustrates each of the 2-1 to 2-3 dummy patterns DMP21, DMP22, and DMP23 as a single layer, but the 2-1 to 2-3 dummy patterns DMP21, DMP22, and DMP23 may include a 2-1 dummy layer D21 (see FIG. 5), a 2-2 dummy layer D22 (see FIG. 5), and a 2-3 dummy layer D23 (see FIG. 5), respectively, and to the 2-1 to 2-3 dummy layers D21, D22, and D23 (see FIG. 5) of the respective 2-1 to 2-3 dummy patterns DMP21, DMP22, and DMP23, the description of the 2-1 to 2-3 dummy layers D21, D22, and D23 described above with reference to FIG. 5 may be equally applied.

In the 2-1 to 2-3 dummy patterns DMP21, DMP22, and DMP23, 2-1, 2-2, and 2-3 dummy openings OP1-D2, OP2-D2, and OP3-D2 overlapping the first, second, and third light emitting openings OP1-E, OP2-E, and OP3-E in a plan view, respectively, may be defined. The 2-1 dummy opening OP1-D2 may defined by inner surfaces of the 2-1 dummy pattern DMP21. The 2-2 dummy opening OP2-D2 may be defined by inner surfaces of the 2-2 dummy pattern DMP22. The 2-3 dummy opening OP3-D2 may defined by inner surfaces of the 2-3 dummy pattern DMP23.

The encapsulation layer TFE may include lower encapsulation inorganic patterns LIL1, LIL2, and LIL3, an encapsulation organic film OL, and an upper encapsulation inorganic film UIL.

In the present embodiment, the lower encapsulation inorganic patterns LIL1, LIL2, and LIL3 may include a first lower encapsulation inorganic pattern LIL1, a second lower encapsulation inorganic pattern LIL2, and a third lower encapsulation inorganic pattern LIL3. The first to third lower encapsulation inorganic patterns LIL1, LIL2, and LIL3 may be provided in the form of patterns spaced apart from each other.

The first to third lower encapsulation inorganic patterns LIL1, LIL2, and LIL3 may cover the first to third light emitting elements ED1, ED2, and ED3, respectively. Specifically, the first to third lower encapsulation inorganic patterns LIL1, LIL2, and LIL3 may be disposed on the first to third cathodes CE1, CE2, and CE3 to cover the first to third cathodes CE1, CE2, and CE3, respectively, and in an embodiment, may also cover the first to third capping patterns CP1, CP2, and CP3 disposed on the first to third cathodes CE1, CE2, and CE3, respectively.

The first lower encapsulation inorganic pattern LIL1 may be in contact with inner surfaces of the second partition wall PW2 defining the 2-1 partition-wall opening OP1-P2, the second lower encapsulation inorganic pattern LIL2 may be in contact with inner surfaces of the second partition wall PW2 defining the 2-2 partition-wall opening OP2-P2, and the third lower encapsulation inorganic pattern LIL3 may be in contact with inner surfaces of the second partition wall PW2 defining the 2-3 partition-wall opening OP3-P2. According to the present embodiment, the first to third lower encapsulation inorganic patterns LIL1, LIL2, and LIL3 may be in contact with inner surfaces of the first upper layer Lib with a high interfacial adhesion, respectively.

In addition, according to the present embodiment, due to the recessed first upper layer L1b, each of the first to third lower encapsulation inorganic patterns LIL1, LIL2, and LIL3 may cover the lower surface L-Pb (see FIG. 5) of the second upper layer L2b and the upper surface U-Pa (see FIG. 5) of the second lower layer L2a exposed from the first upper layer L1b, and a moisture permeation path to the first to third light emitting elements ED1, ED2, and ED3 may be lengthened. Accordingly, by preventing moisture from penetrating into the light emitting elements ED1, ED2, and ED3, it is possible to provide the light emitting elements ED1, ED2, and ED3 with improved process reliability and reduced defects.

FIG. 7A to FIG. 7N are cross-sectional views showing some of steps of a method for manufacturing a display panel according to an embodiment of the invention. In describing the method for manufacturing a display panel of an embodiment with reference to FIG. 7A to FIG. 7N, the same/similar reference numerals are used for the same/similar components as those described with reference to FIG. 1 to FIG. 6, and redundant descriptions thereof will be omitted.

The method for manufacturing a display panel according to the invention includes providing a preliminary display panel including a base layer, an anode disposed on the base layer, and a preliminary pixel-definition layer disposed on the base layer and covering the anode, forming, on the preliminary pixel-definition layer, a first preliminary partition wall including a first lower layer and a second lower layer, forming, on the first preliminary partition wall, a second preliminary partition wall including a first upper layer having an inorganic material and a second upper layer disposed on the first upper layer, patterning the first upper layer and the second upper layer to form a second partition wall having an upper partition-wall opening, patterning the first lower layer and the second lower layer to form a first partition wall having a lower partition-wall opening, forming a light emitting pattern on the anode, and forming, on the light emitting pattern, a cathode in contact with the first partition wall.

Hereinafter, referring to FIG. 7A to FIG. 7N, a method for forming one light emitting element ED (see FIG. 7N) and a method for forming one lower encapsulation inorganic pattern LIL (see FIG. 7N) which covers the same will be described.

Referring in FIG. 7A, the method for manufacturing a display panel according to present embodiment may include providing a preliminary display panel DP-I. The preliminary display panel DP-I provided in the present embodiment may include a circuit element layer DP-CL, an anode AE, a sacrificial pattern CP, and a preliminary pixel-definition layer PDL-I.

The circuit element layer DP-CL may be formed through a typical process of manufacturing a circuit element, and an insulation layer, a semiconductor layer, and a conductive layer are formed by a method such as coating, deposition, and/or the like, and the insulation layer, the semiconductor layer, and the conductive layer are selectively patterned by photolithography and etching processes, thereby forming a semiconductor pattern, a conductive pattern, a signal line, and the like.

The anode AE and the sacrificial pattern SP may be formed by the same patterning process. The preliminary pixel-definition layer PDL-I may cover both the anode AE and the sacrificial pattern SP.

Thereafter, referring to FIG. 7B, the method for manufacturing a display panel according to the present embodiment may include forming, on the preliminary pixel-definition layer PDL-I, a first preliminary partition wall PW1-I including a first lower layer L1a and a second lower layer L2a.

The forming of the first preliminary septum PW1-I may include forming, on the preliminary pixel-definition layer PDL-I, the first lower layer L1a including a first conductive material, and forming, on the first lower layer L1a, the second lower layer L2a including a second conductive material.

The forming of the first lower layer L1a may be performed by a deposition process of the first conductive material. In the present embodiment, the first conductive material may include a metal. In an embodiment, for example, the first conductive material may include at least one of aluminum (Al) or molybdenum (Mo). In an embodiment, for example, the forming of the first lower layer L1a may be performed by a sputtering deposition process.

The forming of the second lower layer L2a may be performed by a deposition process of the second conductive material. In the present embodiment, the second conductive material may include at least one of a metal or a metal nitride. In an embodiment, for example, the second conductive material may include at least one of tungsten (W), molybdenum (Mo), a titanium nitride (TiNₓ), or an aluminum nitride (AlNₓ). In an embodiment, for example, the forming of the second lower layer L2a may be performed by a sputtering deposition process.

Thereafter, referring to FIG. 7C, the method for manufacturing a display panel according to the present embodiment may include forming, on the preliminary pixel-definition layer PDL-I, a second preliminary partition wall PW2-I including a first upper layer L1b and a second upper layer L2b.

The forming of the second preliminary wall PW2-I may include forming, on the first preliminary partition wall PW1-I, a first upper layer L1b including an inorganic material, and forming, on the first upper layer L1b, a second upper layer L2b including a third conductive material.

The forming of the first upper layer L1b may be performed by a deposition process of the inorganic material. In the present embodiment, the first upper layer L1b may include at least one of silicon nitride (SiNₓ), silicon oxide (SiO₂), silicon oxynitride (SiON), or aluminum oxide (Al₂O₃). In an embodiment, for example, the forming of the first upper layer L1b may be performed by a chemical vapor deposition (“CVD”) process or an atomic layer deposition (“ALD”) process.

The forming of the second upper layer L2b may be performed by a deposition process of the third conductive material. In the present embodiment, the third conductive material may include at least one of a metal or a metal nitride. In an embodiment, for example, the third conductive material may include at least one of tungsten (W), molybdenum (Mo), a titanium nitride (TiNₓ), or an aluminum nitride (AlNₓ). In an embodiment, the third conductive material may be the same as the second conductive material. In an embodiment, for example, the forming of the second upper layer L2b may be performed by a sputtering deposition process.

Thereafter, referring to FIG. 7D, the method for manufacturing a display panel according to the present embodiment may include forming a first photoresist layer PR1 on the second preliminary partition wall PW2-I. The first photoresist layer PR1 may be formed by forming a preliminary photoresist layer on the second preliminary partition wall PW2-I, and then patterning the preliminary photoresist layer using a photomask. Through the patterning process, in the first photoresist layer PR1, a photo opening OP-PR overlapping the anode AE in a plan view may be formed.

Thereafter, referring to FIG. 7E and FIG. 7F, the method for manufacturing a display panel according to the present embodiment may include patterning the first and second upper layers L1b and L2b to form a second partition wall PW2 from the second preliminary partition wall PW2-I.

First, as illustrated in FIG. 7E, the patterning of the first and second upper layers L1b and L2b may include performing first etching on the first and second upper layers L1b and L2b. In the first etching step, the first photoresist layer PR1 is used as a mask, and a second preliminary partition-wall opening OP-P2I (or a “preliminary upper partition-wall opening”) may be formed in the second preliminary partition wall PW2-I. The first etching step may be performed by a dry etch process.

The first etching process in the present embodiment may be performed in an etch environment in which the etch selectivity between the first and second upper layers L1b and L2b is substantially the same. Accordingly, an inner surface of the first upper layer L1b and an inner surface of the second upper layer L2b which define the second preliminary partition-wall opening OP-P2I may be substantially aligned.

Thereafter, as illustrated in FIG. 7F, the patterning of the first and second upper layers L1b and L2b may include performing second etching on the first and second upper layers L1b and L2b. In the second etching step, the first photoresist layer PR1 is used as a mask, and a second partition-wall opening OP-P2 (or an upper partition-wall opening) may be formed from the second preliminary partition-wall opening OP-P2I. The second etching step may be performed by a dry etch process or a wet etch process. In an embodiment, for example, in the second etching step, the dry etch may be performed using hydrogen fluoride (“HF”), or the wet etch may be performed using bromine water.

The second partition-wall opening OP-P2 may include a first upper region A1b and a second upper region A2b sequentially disposed in a thickness direction (i.e., the third direction DR3). The first upper layer L1b may include a first upper inner surface S1-Pb defining the first upper region A1b of the second partition-wall opening OP-P2, and the second upper layer L2b may include a second upper inner surface S2-Pb defining the second upper region A2b of the second partition-wall opening OP-P2.

The second etching process in the present embodiment may be performed in an environment in which the etch selectivity between the first and second upper layers L1b and L2b is large. Accordingly, an inner surface of the second partition wall PW2 defining the second partition-wall opening OP-P2 may have an undercut shape in a cross-sectional view. Specifically, since the etch rate of the first upper layer L1b with respect to an etch solution is greater than the etch rate of the second upper layer L2b with respect to the same, the first upper layer L1b may be mainly etched. In this case, depending on conditions of the second etching process, the second upper layer L2b may be partially etched together with the first upper layer L1b, or may not be etched.

In an embodiment, the second upper layer L2b may include at least one of tungsten (W), molybdenum (Mo), a titanium nitride (TiNₓ), or an aluminum nitride (AlNₓ), in which case, the second upper layer L2b may not be etched in the second etching process. That is, in an embodiment of the invention, in the patterning of the first and second upper layers L1b and L2b, after the first etching of the first and second upper layers L1b and L2b, only the first upper layer L1b may be subjected to the second etching step.

Through the second etching process, the first upper inner surface S1-Pb of the first upper layer L1b may be formed by being further recessed inward than the second upper inner surface S2-Pb of the second upper layer L2b. In the second upper layer L2b, a second tip portion TP2 may be formed in the second partition wall PW2 by a portion protruding from the first upper layer L1b.

Thereafter, referring to FIG. 7G and FIG. 7H, the method for manufacturing a display panel according to the present embodiment may include patterning the first and second lower layers L1a and L2a to form a first partition wall PW1 from the first preliminary partition wall PW1-I.

First, as illustrated in FIG. 7G, the patterning of the first and second lower layers L1a and L2a may include performing third etching on the first and second lower layers L1a and L2a. In the third etching step, the first photoresist layer PR1 is used as a mask, and a first preliminary partition-wall opening OP-P1I (or a “preliminary lower partition-wall opening”) may be formed in the first preliminary partition wall PW1-I. The third etching step may be performed by a dry etch process.

The third etching process in the present embodiment may be performed in an etch environment in which the etch selectivity between the first and second lower layers L1a and L2a is substantially the same. Accordingly, an inner surface of the first lower layer L1a and an inner surface of the second lower layer L2a which define the first preliminary partition-wall opening OP-P1I may be substantially aligned.

Thereafter, as illustrated in FIG. 7H, the patterning of the first and second lower layers L1a and L2a may include performing fourth etching on the first and second lower layers L1a and L2a. In the fourth etching step, the first photoresist layer PR1 is used as a mask, and a first partition-wall opening OP-P1 (or a lower partition-wall opening) may be formed from the first preliminary partition-wall opening OP-P1I. The fourth etching step may be performed by a wet etch process.

The first partition-wall opening OP-P1 may include a first lower region A1a and a second lower region A2a sequentially disposed in the thickness direction (i.e., the third direction DR3). The first lower layer L1a may include a first lower inner surface S1-Pa defining the first lower region A1a of the first partition-wall opening OP-P1, and the second lower layer L2a may include a second lower inner surface S2-Pa defining the second lower region A2a of the first partition-wall opening OP-P1.

The fourth etching process in the present embodiment may be performed in an environment in which the etch selectivity between the first and second lower layers L1a and L2a is large. Accordingly, an inner surface of the first partition wall PW1 defining the first partition-wall opening OP-P1 may have an undercut shape in a cross-sectional view. Specifically, since the etch rate of the first lower layer L1a with respect to an etch solution is greater than the etch rate of the second lower layer L2a with respect to the same, the first lower layer L1a may be mainly etched. In this case, depending on conditions of the fourth etching process, the second lower layer L2a may be partially etched together with the first lower layer L1a, or may not be etched. When the second lower layer L2a is not etched, in the patterning of the first and second lower layers L1a and L2a, after the third etching of the first and second lower layers L1a and L2a, only the first lower layer L1a may be subjected to the fourth etching step.

Through the fourth etching process, the first lower inner surface S1-Pa of the first lower layer L1a may be formed by being further recessed inward than the second upper inner surface S2-Pa the second lower layer L2a. In the second lower layer L2a, a first tip portion TP1 may be formed in the first partition wall PW1 by a portion protruding from the first lower layer L1a.

Thereafter, referring to FIG. 7H and FIG. 7I, the method for manufacturing a display panel according to the present embodiment may include etching the preliminary pixel-definition layer PDL-I to form a pixel-definition layer PDL. The etching process of the preliminary pixel-definition layer PDL-I may be performed in a dry etch manner, and may be performed by using the first photoresist layer PR1 and the first and second partition walls PW1 and PW2 (e.g., the second lower layer L2a and the second upper layer L2b) as masks. In the pixel-definition layer PDL, a light emitting opening OP-E overlapping the first and second partition-wall openings OP-P1 and OP-P2 in a plan view may be formed.

Thereafter, referring to FIG. 7I and FIG. 7J, the method for manufacturing a display panel according to the present embodiment may include etching the sacrificial pattern SP. The etching process of the sacrificial pattern SP may be performed in a wet etch manner, and may be performed by using the first photoresist layer PR1 and the first and second partition walls PW1 and PW2 (e.g., the second lower layer L2a and the second upper layer L2b) as masks.

In the sacrificial pattern SP, a sacrificial opening OP-S overlapping the light emitting opening OP-E in a plan view may be formed. By the sacrificial opening OP-S and the light emitting opening OP-E, at least a portion of the anode AE may be exposed from the sacrificial pattern SP and the pixel-definition layer PDL.

The etching process of the sacrificial pattern SP may be performed in an environment in which the etch selectivity between the sacrificial pattern SP and the anode AE is large, through which it is possible to prevent the anode AE from being etched together. That is, by placing the sacrificial pattern SP having a higher etch rate than the anode AE between the pixel-definition layer PDL and the anode AE, it is possible to prevent the anode AE from being etched together and damaged during the etching process.

Thereafter, referring to FIG. 7K, the method for manufacturing a display panel according to present embodiment may include, after removing the first photoresist layer PR1 (see FIG. 7J), forming a light emitting pattern EP, forming a cathode CE, and forming a capping pattern CP.

The forming of the light emitting pattern EP, the forming of the cathode CE, and the forming of the capping pattern CP may each be performed by a deposition process. In an embodiment, the forming of the light emitting pattern EP may be performed by thermal evaporation process, the forming of the cathode CE may be performed by a sputtering process, and the forming of the capping pattern CP may be performed by a thermal evaporation process. However, the embodiment of the invention is not limitation thereto.

In the forming of the light emitting pattern EP, the light emitting pattern EP may be separated by the first tip portion TP1 (see FIG. 7H) formed in the first partition wall PW1, and be disposed in the light emitting opening OP-E and the first partition-wall opening OP-P1. In the forming of the light emitting pattern EP, a 1-1 preliminary dummy layer D11-I separated from the light emitting pattern EP may be formed together on the second partition wall PW2. In addition, in an embodiment, in the forming of the light emitting pattern EP, a 2-1 dummy layer D21 separated from the light emitting pattern EP may be formed together on the second lower layer L2a exposed from the first upper layer L1b.

In the forming of the cathode CE, the cathode CE may be separated by the first tip portion TP1 (see FIG. 7H) formed in the first partition wall PW1, and be disposed in the light emitting opening OP-E and the first partition-wall opening OP-P1. The cathode CE is provided at a high incident angle compared to the light emitting pattern EP, so that the cathode CE may be formed to be in contact with the first lower inner surface S1-Pa of the first lower layer L1a. In the forming of the cathode CE, a 1-2 preliminary dummy layer D12-I separated from the cathode CE may be formed together on the second partition wall PW2. In addition, in an embodiment, in the forming of the cathode CE, a 2-2 dummy layer D22 may be formed together on the second lower layer L2a exposed from the first upper layer L1b. The anode AE, the light emitting pattern EP, and the cathode CE may constitute the light emitting element ED.

In the forming of the capping pattern CP, the capping pattern CP may be separated by the first tip portion TP1 (see FIG. 7H) formed in the first partition wall PW1, and be disposed in the light emitting opening OP-E and the first partition-wall opening OP-P1. In the forming of the capping pattern CP, a 1-3 preliminary dummy layer D13-I separated from the capping pattern CP may be formed together on the second partition wall PW2. In addition, in an embodiment, in the forming of the capping pattern CP, a 2-3 dummy layer D23 may be formed together on the second lower layer L2a exposed from the first upper layer L1b. According to another embodiment of the invention, the forming of the capping pattern CP may be omitted.

The 1-1 to 1-3 preliminary dummy layers D11-I, D12-I, and D13-I form a first preliminary dummy pattern DMP1-I, and a first dummy opening OP-D1 may be formed in the first preliminary dummy pattern DMP1-I. The first dummy opening OP-D1 may be defined by inner surfaces of the 1-1 to 1-3 preliminary dummy layers D11-I, D12-I, D13-I.

The 2-1 to 2-3 dummy layers D21, D22, and D23 form a second dummy pattern DMP2, and a second dummy opening OP-D2 may be formed in the second dummy pattern DMP2. The second dummy opening OP-D2 may be defined by inner surfaces of the 2-1 to 2-3 dummy layers D21, D22, and D23.

Thereafter, referring to FIG. 7I, the method for manufacturing a display panel according to present embodiment may include forming a preliminary lower encapsulation inorganic pattern LIL-I.

The preliminary lower encapsulation inorganic pattern LIL-I may be formed through a deposition process. In an embodiment, the preliminary lower encapsulation inorganic pattern LIL-I includes an inorganic material, and may include, for example, a silicon nitride (SiNₓ). In an embodiment, for example, the preliminary lower encapsulation inorganic pattern LIL-I may be formed through a chemical vapor deposition (CVD) process.

The preliminary lower encapsulation inorganic pattern LIL-I may cover the light emitting element ED. A portion of the preliminary lower encapsulation inorganic pattern LIL-I may be disposed in the light emitting opening OP-E, the first partition-wall opening OP-P1, and the second partition-wall opening OP-P2. Another portion of the preliminary lower encapsulation inorganic pattern LIL-I may cover the first preliminary dummy pattern DMP1-I on the second partition wall PW2.

Thereafter, referring to FIG. 7I and FIG. 7M, the method for manufacturing a display panel according to present embodiment may include forming a second photoresist layer PR2, patterning the preliminary lower encapsulation inorganic pattern LIL-I to form a lower encapsulation inorganic pattern LIL, and patterning the first preliminary dummy pattern DMP1-I to form the first dummy pattern DMP1.

In the forming of the second photoresist layer PR2, the second photoresist layer PR2 may be formed by forming a preliminary photoresist layer, and then patterning the preliminary photoresist layer using a photomask. Through the patterning process, the second photoresist layer PR2 may be formed in the form of a pattern overlapping the light emitting opening OP-E in a plan view.

In the patterning of the preliminary lower encapsulation inorganic pattern LIL-I, the preliminary lower encapsulation inorganic pattern LIL-I may be dry-etched to be patterned such that a portion of the preliminary lower encapsulation inorganic pattern LIL1-I overlapping the remaining anodes except for a corresponding anode AE in a plan view is removed. In an embodiment, for example, when the preliminary lower encapsulation inorganic pattern LIL-I corresponds to a first anode AE1 (see FIG. 6), a portion of the preliminary lower encapsulation inorganic pattern LIL-I overlapping second and third anodes AE2 and AE3 (see FIG. 6) in a plan view may be removed.

From the patterned preliminary encapsulation inorganic pattern LIL-I, the lower encapsulation inorganic pattern LIL overlapping a corresponding light emitting opening OP-E in a plan view may be formed. A portion of the lower encapsulation inorganic pattern LIL may be disposed in the first and second partition-wall openings OP-P1 and OP-P2 and cover the light emitting element ED, and another portion of the lower encapsulation inorganic pattern LIL may be disposed on the second partition wall PW2.

In the patterning the first preliminary dummy pattern DMP1-I, the 1-1 to 1-3 preliminary dummy layers D11-I, D12-I, and D13-I may be dry-etched to remove a portion of the 1-1 to 1-3 preliminary dummy layers D11-I, D12-I, and D13-I overlapping the remaining anodes except for a corresponding anode AE in a plan view. In an embodiment, for example, when the 1-1 to 1-3 preliminary dummy layers D11-I, D12-I, and D13-I correspond to the first anode AE1 (see FIG. 6), a portion of the 1-1 to 1-3 preliminary dummy layers D11-I, D12-I, D13-I overlapping the second and third anodes AE2 and AE3 (see FIG. 6) in a plan view may be removed.

From the patterned 1-1 to 1-3 preliminary dummy layers D11-I, D12-I, and D13-I, the 1-1 to 1-3 dummy layers D11, D12, and D13 overlapping corresponding light emitting openings OP-E in a plan view are formed, so that the first dummy pattern DMP1 including the 1-1 to 1-3 dummy layers D11, D12, and D13 may be formed. The first dummy pattern DMP1 may have a closed-line shape surrounding a corresponding light emitting region PXA (see FIG. 5) on a plane.

Thereafter, referring to FIG. 7N, the method for manufacturing a display panel according to present embodiment may include, after removing the second photoresist layer PR2 (see FIG. 7M), forming an encapsulation organic film OL and an upper encapsulation inorganic film UIL to complete the display panel DP. The encapsulation organic film OL may be formed by applying an organic material in an inkjet manner, but is not limited thereto. The encapsulation organic film OL provides a planarized upper surface. Thereafter, the upper encapsulation inorganic film UIL may be formed by depositing an inorganic material. Through the above, the display panel DP including the base layer BL, the circuit element layer DP-CL, the display element layer DP-OLED, and the encapsulation layer TFE may be formed.

Between the forming of the lower encapsulation inorganic pattern LIL and the completing of the display panel DP, forming, in the first partition wall PW1, the second partition wall PW2, and the pixel-definition layer PDL, a first partition-wall opening, a second partition-wall opening, and a light emitting opening which corresponds to a light emitting region of a different color, forming a light emitting element which provides a different color, and forming a lower encapsulation inorganic pattern which covers the light emitting element which provides a different color may be further performed. Through the above, as illustrated in FIG. 6, the display panel DP including first to third light emitting elements ED1, ED2, and ED3, first to third capping patterns CP1, CP2, and CP3, 1-1 to 1-3 dummy patterns DMP11, DMP12, and DMP13, 2-1 to 2-3 dummy patterns DMP21, DMP22, and DMP23, and first to third lower encapsulation inorganic patterns LIL1, LIL2, and LIL3 may be formed.

According to the invention, a light emitting pattern patterned without a metal mask may be provided, so that a display panel with improved process reliability and easy implementation of a high resolution may be provided.

According to the invention, a first partition wall in contact with a cathode and providing a common voltage to the cathode, and a second partition wall in contact with an encapsulation inorganic pattern on the first partition wall and preventing moisture permeation may be provided. Each of the first partition wall and the second partition wall may have an undercut shape, and the undercut shape of the first partition wall may separate light emitting elements for each pixel, and the undercut shape of the second partition wall may increase a moisture permeation path. In this case, the second partition wall may include a layer composed of an inorganic film, through which the second partition wall may have a high interfacial adhesion with the encapsulation inorganic pattern. Through the above, it is possible to effectively prevent moisture permeation due to a phenomenon in which the encapsulation inorganic pattern is separated during a process, and it is possible to effectively prevent the formation of a moisture permeation path to a light emitting element. Therefore, a light emitting element having improved process reliability and reduced defects and a display panel including the light emitting element may be provided.

According to the invention, a method for manufacturing a display panel capable of easily implementing a high resolution and forming a light emitting element with improved process reliability may be provided.

Although the present invention has been described with reference to preferred embodiments of the present invention, it will be understood by those skilled in the art that various modifications and changes in form and details may be made therein without departing from the spirit and scope of the present invention as set forth in the following claims. Accordingly, the technical scope of the present invention is not intended to be limited to the contents set forth in the detailed description of the specification, but is intended to be defined by the appended claims.

What is claimed is:

1. A display panel comprising:
a base layer;
an anode disposed on the base layer;
a pixel-definition layer defining a light emitting opening which exposes a portion of the anode, and disposed on the base layer;
a first partition wall defining a first partition-wall opening therein overlapping the light emitting opening in a plan view, and disposed on the pixel-definition layer;
a second partition wall defining a second partition-wall opening therein overlapping the first partition-wall opening in the plan view, and disposed on the first partition wall;
a cathode having at least a portion thereof disposed in the first partition-wall opening, being in contact with the first partition wall, and disposed on the anode; and
a light emitting pattern disposed between the anode and the cathode,
wherein:
the first partition wall includes a conductive material; and
the second partition wall includes:
a first upper layer including an inorganic material; and
a second upper layer including a conductive material, and
disposed on the first upper layer.

2. The display panel of claim 1, wherein the first upper layer comprises at least one of silicon nitride, silicon oxide, silicon oxynitride, or aluminum oxide.

3. The display panel of claim 1, wherein the second upper layer comprises at least one of a metal or a metal nitride.

4. The display panel of claim 1, wherein the second upper layer comprises at least one of tungsten, molybdenum, titanium nitride, or aluminum nitride.

5. The display panel of claim 1, further comprising a first dummy pattern disposed on the second partition wall, wherein the first dummy pattern includes:
a 1-1 dummy layer spaced apart from the light emitting pattern, and including a same material as a material of the light emitting pattern; and
a 1-2 dummy layer spaced apart from the cathode, and including a same material as a material of the cathode.

6. The display panel of claim 1, wherein:
the first upper layer comprises a first upper inner surface defining a first upper region of the second partition-wall opening; and
the second upper layer comprises a second upper inner surface defining a second upper region of the second partition-wall opening,
wherein the first upper inner surface is recessed in a direction farther away from the light emitting opening than the second upper inner surface.

7. The display panel of claim 6, further comprising an encapsulation inorganic pattern which covers the cathode, wherein the encapsulation inorganic pattern is in contact with the first upper inner surface.

8. The display panel of claim 7, wherein the encapsulation inorganic pattern covers an entirety of the first upper inner surface.

9. The display panel of claim 7, wherein the first upper layer comprises a same material as a material of the encapsulation inorganic pattern.

10. The display panel of claim 6, wherein the first partition wall comprises:
a first lower layer including a first lower inner surface defining a first lower region of the first partition-wall opening; and
a second lower layer including a second lower inner surface defining a second lower region of the first partition-wall opening,
wherein the first lower inner surface is recessed in a direction farther away from the light emitting opening than the second lower inner surface.

11. The display panel of claim 10, wherein the first upper inner surface is recessed in a direction farther away from the light emitting opening than the second lower inner surface.

12. The display panel of claim 11, wherein a width in which the first upper inner surface is recessed from the second lower inner surface is greater than or equal to a width in which the first lower inner surface is recessed from the second lower inner surface.

13. The display panel of claim 11, further comprising an encapsulation inorganic pattern, some of which are disposed on the cathode and cover the cathode, and others of which are disposed on the second partition wall, wherein the encapsulation inorganic pattern covers a lower surface of the second upper layer exposed from the first upper layer, and cover at least a portion of an upper surface of the second lower layer exposed from the first upper layer.

14. The display panel of claim 13, further comprising a second dummy pattern disposed on a portion of the second lower layer exposed from the first upper layer, wherein the second dummy pattern includes:
a 2-1 dummy layer spaced apart from the light emitting pattern, and including a same material as a material of the light emitting pattern; and
a 2-2 dummy layer spaced apart from the cathode, and including a same material as a material of the cathode, wherein the encapsulation inorganic pattern covers the second dummy pattern.

15. The display panel of claim 10, wherein the cathode is in contact with at least a portion of the first lower inner surface.

16. The display panel of claim 15, further comprising encapsulation inorganic pattern, some of which are disposed on the cathode and cover the cathode, and others of which are disposed on the second partition wall, wherein the encapsulating inorganic pattern is in contact with the second lower inner surface, the first upper inner surface, the second upper inner surface, and a portion of the first lower inner surface not in contact with the cathode.

17. The display panel of claim 10, wherein:
the first lower layer comprises a metal; and
the second lower layer comprises at least one of a metal or a metal nitride.

18. The display panel of claim 10, wherein:
a first tip portion is defined in the first partition wall by the second lower layer protruding more than the first lower layer; and
a second tip portion is defined in the second partition wall by the second upper layer protruding more than the first upper layer.

19. The display panel of claim 1, wherein a bias voltage is configured to be applied to the first partition wall.

20. A method for manufacturing a display panel, the method comprising:
providing a preliminary display panel including a base layer, an anode disposed on the base layer, and a preliminary pixel-definition layer disposed on the base layer and covering the anode;
forming, on the preliminary pixel-definition layer, a first preliminary partition wall including a first lower layer and a second lower layer;
forming, on the first preliminary partition wall, a second preliminary partition wall including a first upper layer having an inorganic material and a second upper layer disposed on the first upper layer;
patterning the first upper layer and the second upper layer to form a second partition wall defining an upper partition-wall opening therein;
patterning the first lower layer and the second lower layer to form a first partition wall defining a lower partition-wall opening therein;
forming a light emitting pattern on the anode; and
forming, on the light emitting pattern, a cathode in contact with the first partition wall.

21. The method of claim 20, wherein the patterning of the first upper layer and the second upper layer comprises:
performing first etching on the first upper layer and the second upper layer to form a preliminary upper partition-wall opening on the second preliminary partition wall; and
performing second etching on the first upper layer and the second upper layer to form the upper partition-wall opening from the preliminary upper partition-wall opening, wherein in the performing of the second etching, an etch rate of the first upper layer is greater than an etch rate of the second upper layer.

22. The method of claim 21, wherein:
the performing of the first etching is performed in a dry etch manner; and
the performing of the second etching is performed in a dry etch manner using hydrogen fluoride or in a wet etch manner using bromine water.

23. The method of claim 20, wherein the patterning of the first upper layer and the second upper layer comprises:
performing first etching on the first upper layer and the second upper layer to form a preliminary upper partition-wall opening on the second preliminary partition wall; and
performing second etching on the first upper layer to form the upper partition-wall opening from the preliminary upper partition-wall opening, wherein in the performing of the second etching, the second upper layer is not etched.

24. The method of claim 20, wherein the second upper layer comprises at least one of a metal or a metal nitride.

25. The method of claim 20, wherein the patterning of the first lower layer and the second lower layer comprises:
performing third etching on the first lower layer and the second lower layer to form a preliminary lower partition-wall opening on the first preliminary partition wall; and
performing fourth etching on the first lower layer and the second lower layer to form the lower partition-wall opening from the preliminary lower partition-wall opening, wherein in the performing of the fourth etching, an etch rate of the first lower layer is greater than an etch rate of the second lower layer.

26. The method of claim 25, wherein:
the performing of the third etching is performed in a dry etch manner; and
the performing of the fourth etching is performed in a wet etch manner.

27. The method of claim 20, wherein:
the first lower layer comprises a metal; and
the second lower layer comprises at least one of a metal or a metal nitride.

28. The method of claim 20, further comprising, after the forming of the cathode, forming an encapsulation inorganic pattern which covers the cathode,
wherein the first upper layer includes a first upper inner surface defining a first upper region of the upper partition-wall opening, and the second upper layer includes a second upper inner surface defining a second upper region of the upper partition-wall opening,
wherein:
the first upper inner surface is recessed in a direction farther away from a light emitting region than the second upper inner surface; and
the encapsulating inorganic pattern covers the first upper inner surface, the second upper inner surface, and a lower surface of the second upper layer exposed from the first upper layer and connected to the second upper inner surface.

29. The method of claim 20, further comprising, after the patterning of the first lower layer and the second lower layer and before the forming of the light emitting pattern on the anode, patterning the preliminary pixel-definition layer to form a pixel-definition layer defining a light emitting opening therein, wherein at least a portion of the light emitting pattern is formed in the light emitting opening and the partition-wall opening.
